(19) United States
(12) Patent Application Publication
(10) Pub. No.: US 2025/0076420 A1
(43) Pub. Date: Mar. 6, 2025

(54) MAGNETIC SENSOR, MAGNETIC SENSOR DEVICE, AND MAGNETIC SENSOR SYSTEM

(71) Applicant: TDK CORPORATION, Tokyo (JP)

(72) Inventors: Kazuya WATANABE, Tokyo (JP); Hiraku HIRABAYASHI, Tokyo (JP)

(73) Assignee: TDK CORPORATION, Tokyo (JP)

(21) Appl. No.: 18/810,066

(22) Filed: Aug. 20, 2024

(30) Foreign Application Priority Data
Sep. 5, 2023 (JP) 2023-143828

(51) Int. Cl. G01R 33/09

(52) U.S. Cl. CPC G01R 33/09

(57) ABSTRACT

A magnetic sensor includes first to third structural bodies having a structure for a magnetic detection element to detect a target magnetic field at first to third positions away from a reference axis, respectively, and first to third detection circuits including first to third magnetic detection elements, respectively. The second position is a position rotated from the first position by (120+360×m)° circumferentially about the reference axis. The third position is a position rotated from the first position by (240+360×n)° circumferentially about the reference axis.

### CROSS REFERENCE TO RELATED APPLICATIONS

This application claims the benefit of Japanese Priority Patent Application No. 2023-143828 filed on Sep. 5, 2023, the entire contents of which are incorporated herein by reference.

### BACKGROUND

The technology relates to a magnetic sensor including a structural body having a structure for a magnetic detection element to detect a specific component of a magnetic field, and a magnetic sensor device and a magnetic sensor system each including the magnetic sensor.

In recent years, angle sensors that generate an angle detection value having a correspondence with an angle to be detected have been widely used in various applications, including detection of the rotational position of a steering wheel or a power steering motor in an automobile. Examples of the angle sensors include one using a magnetic detection element. An angle sensor system using a magnetic detection element typically includes a magnetic field generator that generates a magnetic field to be detected whose direction rotates with the rotation or linear motion of a target object. An example of the magnetic field generator is a magnet. The angle to be detected has a correspondence with an angle that the direction of the magnetic field to be detected at a reference position forms with a reference direction.

US 2023/0152125 A1 discloses a magnetic angle sensor including three magnetoresistive elements and a magnetic source configured to be movable relative to the three magnetoresistive elements. The three magnetoresistive elements are arranged in a star shape or a regular triangle shape. An angle signal indicating the rotation angle of the magnetic source is calculated from the output signals of the three magnetoresistive elements.

Aside from the magnetic field to be detected, a noise magnetic field other than the magnetic field to be detected is applied to the magnetic detection elements in some cases. Examples of the noise magnetic field include the geomagnetic field and a leakage magnetic field from a motor. If such a noise magnetic field is applied to the magnetic detection elements, each magnetic detection element detects a composite magnetic field of the magnetic field to be detected and the noise magnetic field. If the direction of the magnetic field to be detected differs from that of the noise magnetic field, an error occurs in the angle detection value.

When a noise magnetic field is applied, the output signal of the magnetic detection element varies. The variation width of the output signal changes depending on the angle that the direction of the noise magnetic field forms with the sensitivity axis of the magnetic detection element. In a magnetic sensor including a plurality of magnetic detection elements having sensitivity axes in respective different directions, like the magnetic angle sensor disclosed in US 2023/0152125 A1, the variation widths of the respective output signals of the plurality of magnetic detection elements due to a noise magnetic field thus differ from each other. To reduce the error in the angle detection value, the effect of the noise magnetic field therefore needs to be sufficiently reduced before the calculation of the angle detection value.

### SUMMARY

A magnetic sensor according to one embodiment of the technology is configured to detect a target magnetic field including a component in a direction parallel to a reference axis. The magnetic sensor according to one embodiment of the technology includes: a first structural body having a structure for a first magnetic detection element to detect a first partial magnetic field that is the target magnetic field at a first position away from the reference axis; a second structural body having a structure for a second magnetic detection element to detect a second partial magnetic field that is the target magnetic field at a second position away from the reference axis; a third structural body having a structure for a third magnetic detection element to detect a third partial magnetic field that is the target magnetic field at a third position away from the reference axis; a first detection circuit including the first magnetic detection element and configured to generate a first detection signal that changes periodically depending on a periodic change in the first partial magnetic field; a second detection circuit including the second magnetic detection element and configured to generate a second detection signal that changes periodically depending on a periodic change in the second partial magnetic field; and a third detection circuit including the third magnetic detection element and configured to generate a third detection signal that changes periodically depending on a periodic change in the third partial magnetic field.

The first detection signal, the second detection signal, and the third detection signal include respective periodic components that change with the same period. The second position is a position rotated from the first position by an angle equivalent to an electrical angle of (120+360×m)° circumferentially about the reference axis, and the third position is a position rotated from the first position by an angle equivalent to an electrical angle of (240+360×n)° circumferentially about the reference axis, where the period of the periodic components is an electrical angle of 360°, and m and n are both integers greater than or equal to 0.

A magnetic sensor device according to one embodiment of the technology includes the magnetic sensor according to one embodiment of the technology, and a processor configured to generate an angle detection value having a correspondence with a target angle based on the first detection signal, the second detection signal, and the third detection signal.

A magnetic sensor system according to a first aspect of one embodiment of the technology includes the magnetic sensor according to one embodiment of the technology and a magnetic field generator configured to generate the target magnetic field. The magnetic sensor and the magnetic field generator are configured so that a strength of the component of the target magnetic field in the direction parallel to the reference axis at each of the first, second, and third positions changes when at least either the magnetic sensor or the magnetic field generator rotates about the reference axis.

A magnetic sensor system according to a second aspect of one embodiment of the technology includes a magnetic field generator configured to generate a target magnetic field, and a magnetic sensor configured to detect the target magnetic field. The magnetic sensor includes a first structural body having a structure for a first magnetic detection element to detect a first partial magnetic field that is the target magnetic field at a first position away from the magnetic field generator in a first direction, a second structural body having a structure for a second magnetic detection element to detect a second partial magnetic field that is the target magnetic field at a second position away from the magnetic field generator in the first direction, a third structural body having a structure for a third magnetic detection element to detect a third partial magnetic field that is the target magnetic field at a third position away from the magnetic field generator in the first direction, a first detection circuit including the first magnetic detection element, a second detection circuit including the second magnetic detection element, and a third detection circuit including the third magnetic detection element.

The magnetic field generator is a magnetic scale including a plurality of pairs of N and S poles arranged alternately. The magnetic sensor and the magnetic field generator are configured so that strengths of components of the target magnetic field in the first direction at the first, second, and third positions change when at least either the magnetic sensor or the magnetic field generator operates in a direction parallel to a second direction intersecting the first direction. The second position is a position away from the first position by (λ/3+m×λ) in the second direction, and the third position is a position away from the first position by (2λ/3+n×2) in the second direction, where 2 is a center-to-center distance of two adjacent N poles with an S pole therebetween in the magnetic field generator, and m and n are both integers greater than or equal to 0.

The magnetic sensor according to one embodiment of the technology includes the first to third structural bodies located at respective predetermined positions. According to one embodiment of the technology, the effect of the noise magnetic field can thereby be reduced.

Other and further objects, features and advantages of the technology will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a perspective view showing a magnetic sensor system according to a first example embodiment of the technology.

FIG. 2 is a plan view showing the magnetic sensor system according to the first example embodiment of the technology.

FIG. 3 is an explanatory diagram for describing a target magnetic field in a first example embodiment of the technology.

FIG. 4 is a circuit diagram showing a configuration of the magnetic sensor device according to the first example embodiment of the technology.

FIG. 5 is a perspective view showing a part of both a detection circuit and a structural body in the first example embodiment of the technology.

FIG. 6 is a plan view showing a part of both the detection circuit and the structural body in the first example embodiment of the technology.

FIG. 7 is a side view showing a part of both the detection circuit and the structural body in the first example embodiment of the technology.

FIG. 8 is a perspective view showing a layered film of a magnetoresistive element in the first example embodiment of the technology.

FIG. 9 is a circuit diagram showing a configuration of a magnetic sensor device according to a second example embodiment of the technology.

FIG. 10 is a circuit diagram schematically showing a configuration of a magnetic sensor according to a third example embodiment of the technology.

FIG. 11 is a circuit diagram schematically showing a configuration of a magnetic sensor according to a fourth example embodiment of the technology.

FIG. 12 is a circuit diagram schematically showing a configuration of a magnetic sensor according to a fifth example embodiment of the technology.

FIG. 13 is a perspective view showing a magnetic sensor system according to a sixth example embodiment of the technology.

FIG. 14 is a plan view showing the magnetic sensor system according to the sixth example embodiment of the technology.

FIG. 15 is a circuit diagram schematically showing a configuration of a magnetic sensor according to a seventh example embodiment of the technology.

FIG. 16 is a plan view showing a part of both a detection circuit and a structural body in the seventh example embodiment of the technology.

FIG. 17 is a sectional view showing a part of both the detection circuit and the structural body in the seventh example embodiment of the technology.

FIG. 18 is a perspective view showing a magnetic sensor system according to an eighth example embodiment of the technology.

FIG. 19 is a plan view showing the magnetic sensor system according to the eighth example embodiment of the technology.

FIG. 20 is a perspective view showing a layered film of a magnetoresistive element in a ninth example embodiment of the technology.

FIG. 21 is a plan view showing a free layer of the layered film of the magnetoresistive element in the ninth example embodiment of the technology.

FIG. 22 is a plan view showing the free layer when a target magnetic field is applied to the magnetoresistive element in the ninth example embodiment of the technology.

FIG. 23 is a plan view showing the free layer when a target magnetic field is applied to the magnetoresistive element in the ninth example embodiment of the technology.

### DETAILED DESCRIPTION

An object of the technology is to provide a magnetic sensor capable of reducing the effect of a noise magnetic field, and a magnetic sensor device and a magnetic sensor system each including the magnetic sensor.

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions. Note that the description is given in the following order.

### First Example Embodiment

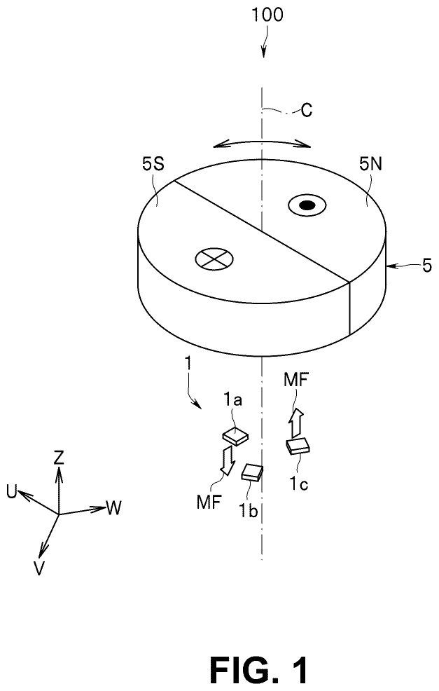

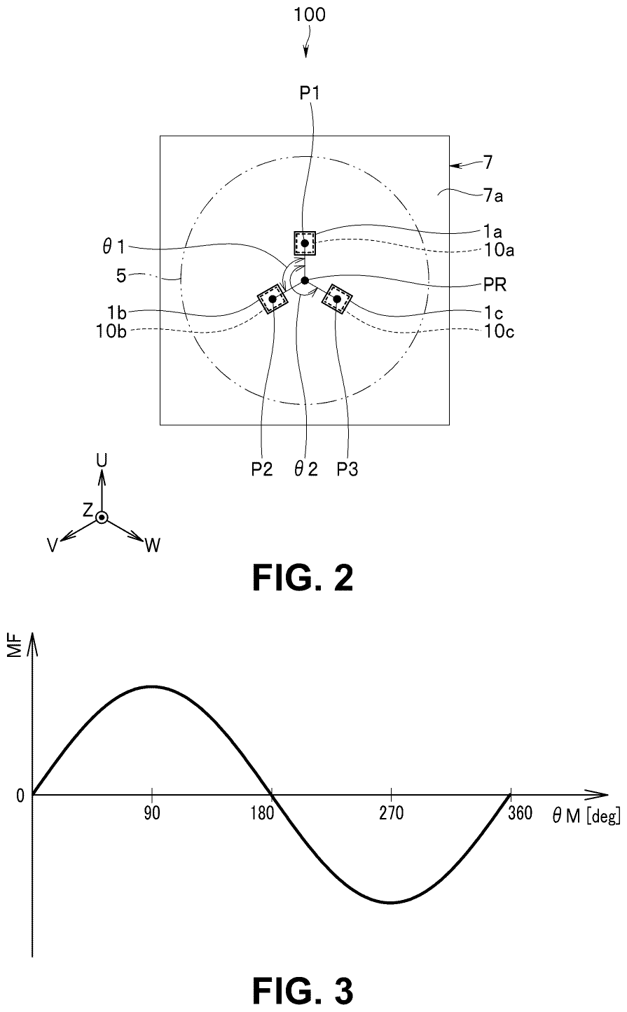

A configuration of a magnetic sensor system according to a first example embodiment of the technology will initially be described with reference to FIGS. 1 and 2. FIG. 1 is a perspective view showing a magnetic sensor system 100 according to the example embodiment. FIG. 2 is a plan view showing the magnetic sensor system 100 according to the example embodiment. The magnetic sensor system 100 according to the example embodiment is a magnetic angle sensor system, and includes a magnetic sensor 1 according to the example embodiment and a magnetic field generator 5.

The magnetic field generator 5 generates a magnetic field to be detected related to an angle to be detected. The magnetic field to be detected by the magnetic sensor 1 will hereinafter be referred as a target magnetic field MF. The magnetic field generator 5 in the example embodiment is a cylindrical magnet. The magnetic field generator 5 has an N pole 5N and an S pole 5S symmetrically arranged about an imaginary plane including the center axis of the cylinder. The magnetic field generator 5 rotates about the center axis of the cylinder.

The N pole 5N has a magnetization in a direction parallel to a reference axis C. The S pole 5S has a magnetization in the opposite direction to that of the magnetization of the N pole 5N. In FIG. 1, the direction of the magnetization of the N pole 5N is shown as an upward direction, and the direction of the magnetization of the S pole 5S is shown as a downward direction.

In FIG. 1, the target magnetic field MF is represented by the arrows denoted by the reference symbol MF. The target magnetic field MF includes a component in a direction parallel to the reference axis C. The magnetic sensor 1 and the magnetic field generator 5 are configured so that the strength of the component of the target magnetic field MF in the direction parallel to the reference axis C changes at a specific position away from the reference axis C when at least either the magnetic sensor 1 or the magnetic field generator 5 rotates about the reference axis C. In particular, in the example embodiment, the magnetic field generator 5 is configured to rotate. The strength of the target magnetic field MF at a specific position has a correspondence with a rotation angle θM of the magnetic field generator 5, and changes with the rotation of the magnetic field generator 5.

As employed herein, the angle to be detected will be referred to as a target angle and denoted by the symbol 0. The target angle θ in the example embodiment is an angle corresponding to the rotation angle θM of the magnetic field generator 5.

The magnetic sensor 1 is configured to detect the target magnetic field MF and generate at least one detection signal having a correspondence with the target angle θ. In particular, in the example embodiment, the magnetic sensor 1 is configured to detect the target magnetic field MF at each of a plurality of specific positions away from the reference axis C. In the following description, the target magnetic field MF at each of the plurality of specific positions will be described to include as its main component a component in the direction parallel to the reference axis C.

FIG. 3 is an explanatory diagram for describing the target magnetic field MF at a specific position. In FIG. 3, the horizontal axis indicates the rotation angle θM of the magnetic field generator 5, and the vertical axis the strength of the target magnetic field MF. In the example embodiment, the strength of the target magnetic field MF is expressed by a positive value if the direction of the target magnetic field MF agrees with a first direction parallel to the reference axis C. The strength of the target magnetic field MF is expressed by a negative value if the direction of the target magnetic field MF agrees with a second direction opposite to the first direction.

As shown in FIG. 3, the strength of the target magnetic field MF at a specific position changes periodically with the rotation of the magnetic field generator 5. In particular, in the example embodiment, the strength of the target magnetic field MF at a specific position changes by one period as the magnetic field generator 5 rotates one revolution, i.e., the rotation angle θM changes by 360°.

The magnetic sensor 1 includes a first electronic component 1a including a first detection circuit 10a, a second electronic component 1b including a second detection circuit 10b, and a third electronic component 1c including a third detection circuit 10c. The first to third detection circuits 10a to 10c, i.e., the first to third electronic components 1a to 1c are disposed to oppose to one end surface of the magnetic field generator 5, i.e., the cylindrical magnet.

The first to third electronic components 1a to 1c may each have a chip form, or a package form sealed with a sealing resin. If each of the first to third electronic components 1a to 1c has a chip form, the magnetic sensor 1 may have a single package form with the first to third electronic components 1a to 1c sealed with a sealing resin.

The first detection circuit 10a is configured to detect a first partial magnetic field that is the target magnetic field MF at a first position P1 away from the reference axis C. The second detection circuit 10b is configured to detect a second partial magnetic field that is the target magnetic field MF at a second position P2 away from the reference axis C. The third detection circuit 10c is configured to detect a third partial magnetic field that is the target magnetic field MF at a third position P3 away from the reference axis C.

The description of the change in the strength of the target magnetic field MF at a specific position, made with reference to FIG. 3, also applies to the first to third partial magnetic fields. The strength of each of the first to third partial magnetic fields changes periodically with the rotation of the magnetic field generator 5. The first detection circuit 10a is configured to generate a first detection signal S1 that changes periodically depending on the periodic change in the first partial magnetic field. The second detection circuit 10b is configured to generate a second detection signal S2 that changes periodically depending on the periodic change in the second partial magnetic field. The third detection circuit 10c is configured to generate a third detection signal S3 that changes periodically depending on the periodic change in the third partial magnetic field.

The first to third detection signals S1 to S3 include respective periodic components that change with the same period. In particular, in the example embodiment, the periodic components change periodically with a predetermined signal period to trace ideal sinusoidal curves (including sine and cosine waveforms). As the magnetic field generator 5 rotates one revolution, i.e., the rotation angle θM changes by 360°, the periodic components change by one period.

The first to third positions P1 to P3 will now be described in detail. Each of the first to third positions P1 to P3 may be located on an imaginary plane perpendicular to the reference axis C. Alternatively, at least one of the first to third positions P1 to P3 may be located away from the imaginary plane. The imaginary plane will hereinafter be referred to as a reference plane. The position where the reference axis C intersects the reference plane will be referred to as a reference position PR. In the following description, the first to third positions P1 to P3 fall on the reference plane. The first to third positions P1 to P3 may be located on an imaginary circle about the reference position PR.

As shown in FIG. 2, the second position P2 is a position rotated from the first position P1 by an angle θ1 circumferentially about the reference axis C. The third position P3 is a position rotated from the first position P1 by an angle θ2 circumferentially about the reference axis C.

Suppose that the period of the periodic components is an electrical angle of 360°, and m and n are both integers greater than or equal to 0. The angle θ1 is equivalent to an electrical angle of (120+360×m)°. The angle θ2 is equivalent to an electrical angle of (240+360×n)°.

Suppose also that the number of pairs of N and S poles 5N and 5S in the magnetic field generator 5 is k. The angle θ1 is (120/k+360×m/k)°. The angle θ2 is (240/k+360×n/k)°.

In the example embodiment, m and n are both 0, and k is 1. The second position P2 is thus a position rotated from the first position P1 by 120° circumferentially about the reference axis C (counterclockwise in FIG. 2). The third position P3 is a position rotated from the first position P1 by 240° circumferentially about reference axis C (counterclockwise in FIG. 2). In particular, in the present example embodiment, the physical angle equivalent to the electrical angle of 120° is also 120°. The physical angle equivalent to the electrical angle of 240° is also 240°.

The first electronic component 1a is disposed in an area including the first position P1. The second electronic component 1b is disposed in an area including the second position P2. The third electronic component 1c is disposed in an area including the third position P3.

Now, a U direction, a V direction, a W direction, and a Z direction will be defined as shown in FIGS. 1 and 2. In the example embodiment, the direction parallel to the reference axis C shown in FIG. 1 and upward in FIG. 1 is defined as the Z direction. In FIG. 2, the Z direction is shown as a direction from the far side to the near side of FIG. 2. A direction orthogonal to the Z direction and from the reference axis C toward the first position P1 is defined as the U direction. A direction orthogonal to the Z direction and from the reference axis C toward the second position P2 is defined as the V direction. A direction orthogonal to the Z direction and from the reference axis C toward the third position P3 is defined as the W direction. In particular, in the example embodiment, the V direction is the direction rotated from the U direction counterclockwise in FIG. 2 by 120°. The W direction is the direction rotated from the V direction counterclockwise in FIG. 2 by 120°, and from the U direction clockwise in FIG. 2 by 120°. The opposite direction to the U direction is referred to as a −U direction. The opposite direction to the V direction is referred to as a −V direction. The opposite direction to the W direction is referred to as a −W direction. The opposite direction to the Z direction is referred to as a −Z direction. A coordinate system with reference to the reference axis C will hereinafter be referred to as a reference coordinate system.

In the reference coordinate system and an orthogonal coordinate system to be described below, the term “above” hereinafter refers to positions located forward of a reference position in the Z direction, and “below” refers to positions opposite from the “above” positions with respect to the reference position.

The magnetic sensor 1 further includes a support 7 that supports the first to third electronic components 1a to 1c. The support 7 is located at a predetermined distance from the magnetic field generator 5 in the direction parallel to the reference axis C. The support 7 has a top surface 7a opposed to the magnetic field generator 5. The top surface 7a may be perpendicular to the reference axis C, i.e., the Z direction. In such a case, the reference plane may be the top surface 7a or a plane parallel to the top surface 7a. In the example shown in FIG. 2, the first to third electronic components 1a to 1c are disposed on the top surface 7a of the support 7.

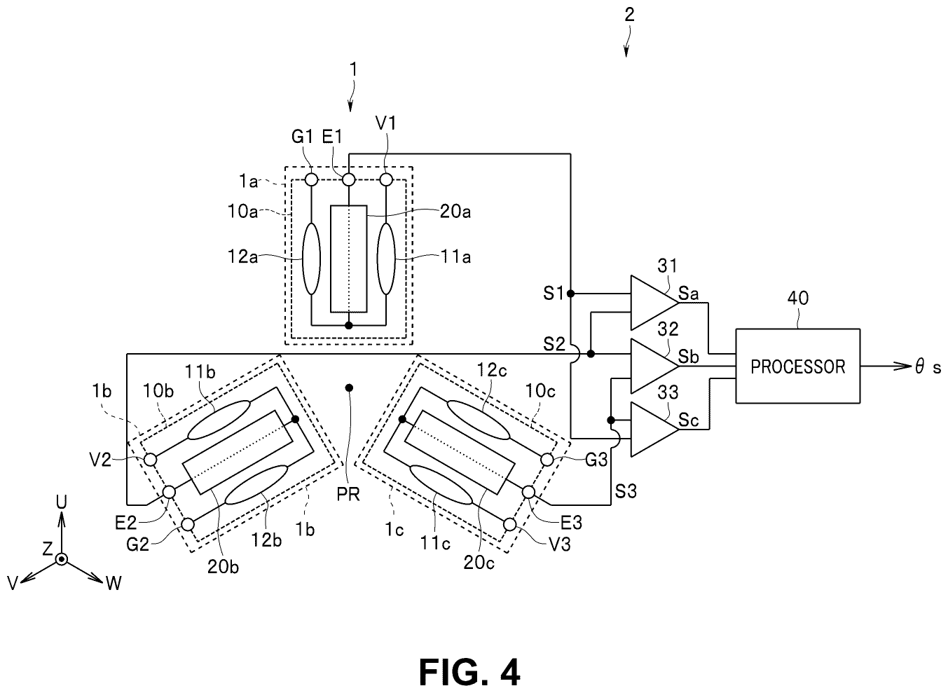

Next, a configuration of the magnetic sensor 1 will be described in detail with reference to FIG. 4. FIG. 4 is a circuit diagram showing a configuration of a magnetic sensor device according to the example embodiment.

A magnetic sensor device 2 according to the example embodiment includes the magnetic sensor 1 according to the example embodiment and a processor 40. The processor 40 is configured to generate an angle detection value θs having a correspondence with the target angle θ based on the first to third detection signals S1 to S3. For example, the processor 40 can be implemented by an application-specific integrated circuit (ASIC) or a microcomputer. The processor 40 may be included in the support 7 shown in FIG. 2, or located away from the first to third electronic components 1a to 1c and the magnetic field generator 5.

The magnetic sensor 1 further includes a first structural body 20a, a second structural body 20b, and a third structural body 20c. The first electronic component 1a includes the first detection circuit 10a and the first structural body 20a. The second electronic component 1b includes the second detection circuit 10b and the second structural body 20b. The third electronic component 1c includes the third detection circuit 10c and the third structural body 20c.

The first structural body 20a has a structure for a first magnetic detection element to detect the target magnetic field MF at the first position P1 (first partial magnetic field). The first magnetic detection element has sensitivity in a direction intersecting the reference axis C. In other words, the first structural body 20a has a structure for the first magnetic detection element having sensitivity in a direction intersecting the reference axis C to detect the target magnetic field MF including a component in the direction parallel to the reference axis C as its main component.

The first detection circuit 10a includes the first magnetic detection element. The first magnetic detection element changes its characteristics depending on a change in the strength of the component of the target magnetic field MF in the direction parallel to the reference axis C. In particular, in the present example embodiment, the first detection circuit 10a includes two magnetoresistive elements (hereinafter, referred to as MR elements) 11a and 12a as the first magnetic detection element. The first detection circuit 10a further includes a power supply port V1, a ground port G1, and an output port E1. The MR element 11a is provided between the power supply port V1 and the output port E1 in circuit configuration. The MR element 12a is provided between the ground port G1 and the output port E1 in the circuit configuration. A voltage or current of predetermined magnitude is applied to the power supply port V1. The ground port G1 is grounded. In this application, the expression “in (the) circuit configuration” is used to indicate a layout in a circuit diagram and not a layout in a physical configuration.

The second structural body 20b has a structure for a second magnetic detection element to detect the target magnetic field MF at the second position P2 (second partial magnetic field). The second magnetic detection element has sensitivity in a direction intersecting the reference axis C. In other words, the second structural body 20b has a structure for the second magnetic detection element having sensitivity in a direction intersecting the reference axis C to detect the target magnetic field MF including a component in the direction parallel to the reference axis C as its main component.

The second detection circuit 10b includes the second magnetic detection element. The second magnetic detection element changes its characteristics depending on a change in the strength of the component of the target magnetic field MF in the direction parallel to the reference axis C. In particular, in the example embodiment, the second detection circuit 10b includes two MR elements 11b and 12b as the second magnetic detection element. The second detection circuit 10b further includes a power supply port V2, a ground port G2, and an output port E2. The MR element 11b is provided between the power supply port V2 and the output port E2 in the circuit configuration. The MR element 12b is provided between the ground port G2 and the output port E2 in the circuit configuration. A voltage or current of predetermined magnitude is applied to the power supply port V2. The ground port G2 is grounded.

The third structural body 20c has a structure for a third magnetic detection element to detect the target magnetic field MF at the third position P3 (third partial magnetic field). The third magnetic detection element has sensitivity in a direction intersecting the reference axis C. In other words, the third structural body 20c has a structure for the third magnetic detection element having sensitivity in a direction intersecting the reference axis C to detect the target magnetic field MF including a component in the direction parallel to the reference axis C as its main component.

The third detection circuit 10c includes the third magnetic detection element. The third magnetic detection element changes its characteristics depending on a change in the strength of the component of the target magnetic field MF in the direction parallel to the reference axis C. In particular, in the example embodiment, the third detection circuit 10c includes two MR elements 11c and 12c as the third magnetic detection element. The third detection circuit 10c further includes a power supply port V3, a ground port G3, and an output port E3. The MR element 11c is provided between the power supply port V3 and the output port E3 in the circuit configuration. The MR element 12c is provided between the ground port G3 and the output port E3 in the circuit configuration. A voltage or current of predetermined magnitude is applied to the power supply port V3. The ground port G3 is grounded.

The first to third structural bodies 20a to 20c and the first to third detection circuits 10a to 10c are disposed on the top surface 7a of the support 7 shown in FIG. 2.

The magnetic sensor device 2 further includes differential detectors 31, 32, and 33. The differential detector 31 outputs a signal corresponding to a potential difference between the output ports E1 and E2 as a first signal Sa. The differential detector 32 outputs a signal corresponding to a potential difference between the output ports E2 and E3 as a second signal Sb. The differential detector 33 outputs a signal corresponding to a potential difference between the output ports E3 and E1 as a third signal Sc.

The first to third signals Sa to Sc may be generated by digital signal processing. More specifically, each of the differential detectors 31, 32, and 33 may be configured with a differential analog-to-digital converter such as an ASIC and a microcomputer. In such a case, the differential detectors 31, 32, and 33 may be integrated with the processor 40. Alternatively, the first to third signals Sa to Sc may be generated by analog signal processing. More specifically, each of the differential detectors 31, 32, and 33 may be configured with a circuit using an operational amplifier. In such a case, the differential detectors 31, 32, and 33 may be integrated with the processor 40 or separate from the processor 40.

Any pair of a detection circuit and a structural body among the pair of the first detection circuit 10a and the first structural body 20a, the pair of the second detection circuit 10b and the second structural body 20b, and the pair of the third detection circuit 10c and the third structural body 20c will be denoted by the reference numerals 10 and 20, respectively. Of the MR elements included in the detection circuit 10, one corresponding to the MR element 11a, 11b, or 11c will be denoted by the reference numeral 11, and one corresponding to the MR element 12a, 12b, or 12c by the reference numeral 12.

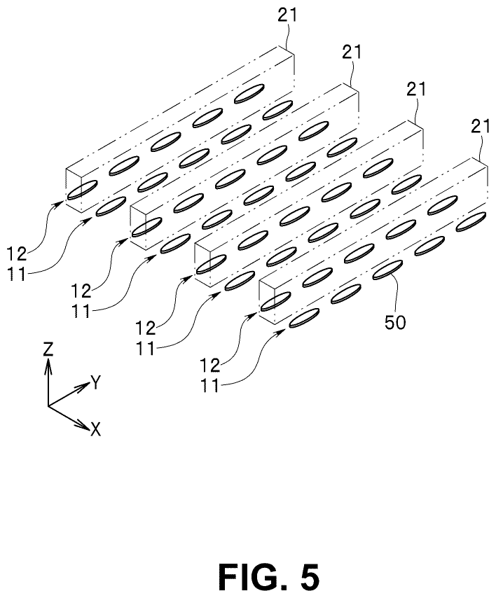

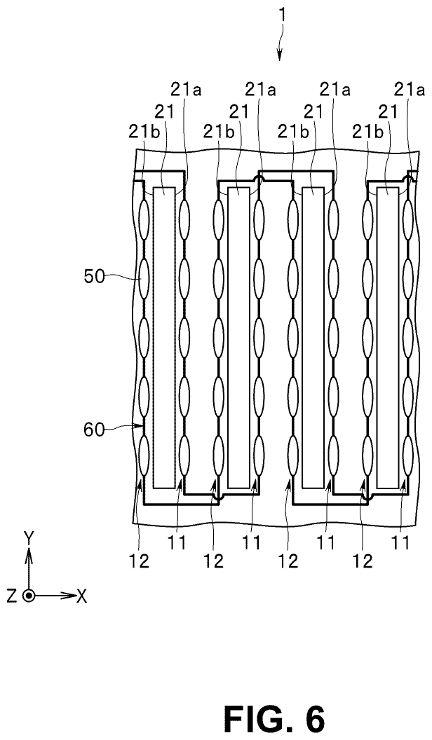

A configuration of the detection circuit 10 and the structural body 20 will now be described in detail with reference to FIGS. 5 to 7. FIG. 5 is a perspective view showing a part of both the detection circuit 10 and the structural body 20. FIG. 6 is a plan view showing a part of both the detection circuit 10 and the structural body 20.

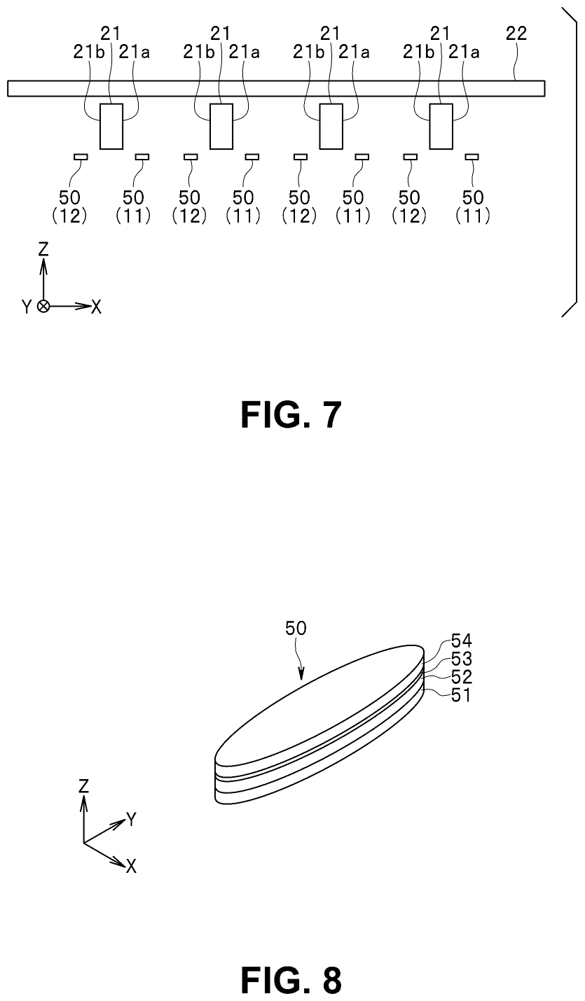

FIG. 7 is a side view showing a part of both the detection circuit 10 and the structural body 20.

Here, as shown in FIGS. 5 to 7, an X direction, a Y direction, and a Z direction are defined. The X, Y, and Z directions are orthogonal to one another. The opposite directions to the X, Y, and Z directions are defined as −X, −Y, and −Z directions, respectively. An orthogonal coordinate system defined by the X, Y, and Z directions shown in FIGS. 5 to 7 is a coordinate system defined with reference to the pair of the detection circuit 10 and the structural body 20. The Z direction of this orthogonal coordinate system agrees with that of the reference coordinate system defined based on the reference axis C shown in FIGS. 1 and 2.

The structural body 20 includes at least one yoke formed of a soft magnetic body. The at least one yoke is configured to generate a magnetic field component in a direction parallel to a direction intersecting the direction parallel to the Z direction based on the target magnetic field MF. Note that the direction intersecting the direction parallel to the Z direction is also a direction intersecting the reference axis C shown in FIGS. 1 and 2. In the present example embodiment, the at least one yoke has a shape long in a direction parallel to the Y direction when seen from above. The at least one yoke receives the target magnetic field MF and generates a magnetic field component in a direction parallel to the X direction.

In particular, in the example embodiment, as shown in FIGS. 5 to 7, the structural body 20 includes a plurality of yokes 21 arranged in the X direction as the at least one yoke. Each of the plurality of yokes 21 has a rectangular solid shape long in the Y direction, for example. The plurality of yokes 21 have the same shape. Each of the plurality of yokes 21 has a first end surface 21a located at the end in the X direction and a second end surface 21b located at the end in the −X direction.

The MR elements 11 and 12 are located at positions where magnetic field components generated by the plurality of yokes 21 are applied. In particular, in the example embodiment, the MR elements 11 and 12 are located near the ends of the respective yokes 21 in the −Z direction.

Each of the MR elements 11 and 12 includes at least one layered film. In particular, in the example embodiment, each of the MR elements 11 and 12 includes a plurality of layered films 50 as the at least one layered film. The detection circuit 10 further includes wiring portions 60 electrically connecting the plurality of layered films 50. In FIGS. 5 and 7, the wiring portions 60 are omitted.

Each of the plurality of layered films 50 of the MR element 11 is located near the first end surface 21a of a yoke 21 so that the magnetic field component generated by the yoke 21 is applied thereto. The plurality of layered films 50 of the MR element 11 are arranged in rows along the plurality of yokes 21, with several layered films 50 in each row. The plurality of layered films 50 of the MR element 11 are connected in series by wiring portions 60.

Each of the plurality of layered films 50 of the MR element 12 is located near the second end surface 21b of a yoke 21 so that the magnetic field component generated by the yoke 21 is applied thereto. The plurality of layered films 50 of the MR element 12 are arranged in rows along the plurality of yokes 21, with several layered films 50 in each row. The plurality of layered films 50 of the MR element 12 are connected in series by wiring portions 60.

The direction of the magnetic field components received by the plurality of layered films 50 of the MR element 12 is opposite to that of the magnetic field components received by the plurality of layered films 50 of the MR element 11.

The wiring portions 60 include a plurality of lower electrodes and a plurality of upper electrodes. Each of the plurality of lower electrodes has a long slender shape in the Y direction. There is a gap formed between two lower electrodes adjacent in the Y direction. Layered films 50 are disposed on the top surface of each lower electrode, near both ends in the Y direction. Each of the plurality of upper electrodes electrically connects two adjacent layered films 50 disposed on two lower electrodes adjacent in the Y direction. The wiring portions 60 in each of the MR elements 11 and 12 further include a plurality of connection electrodes each connecting, in series, two rows of layered films 50 adjacent in the direction parallel to the X direction. The plurality of layered films 50 in each of the MR elements 11 and 12 are connected in series by the plurality of lower electrodes, the plurality of upper electrodes, and the plurality of connection electrodes.

As shown in FIG. 7, the magnetic sensor 1 further includes at least one shield 22 that is formed of a soft magnetic body and intended to shield the MR elements 11 and 12 from an external magnetic field in a direction orthogonal to the Z direction. The at least one shield 22 is located to overlap the plurality of yokes 21 when seen in a direction parallel to the Z direction, e.g., from above. The plurality of yokes 21 lie within the outer edges of the at least one shield 22 when seen from above. As shown in FIG. 7, the at least one shield 22 may be located forward of the plurality of yokes 21 in the Z direction. Alternatively, the at least one shield 22 may be located so that the MR elements 11 and 12 are interposed between the plurality of yokes 21 and the at least one shield 22.

The magnetic sensor 1 may include three shields as the at least one shield 22. In such a case, each of the first to third electronic components 1a to 1c includes one of the three shields. Alternatively, the magnetic sensor 1 may include one shield as the at least one shield 22. In such a case, the shield is located to overlap the plurality of yokes 21 of each of the first to third structural bodies 20a to 20c when seen in a direction parallel to the Z direction, e.g., from above.

The magnetic sensor 1 further includes a not-shown substrate and a not-shown insulating layer. The detection circuits 10, the structural bodies 20, and the at least one shield 22 are disposed on the substrate and integrated by the insulating layer.

The magnetic sensor 1 further includes a not-shown plurality of electrode pads. The plurality of electrode pads include power supply port electrode pads corresponding to the power supply ports V1, V2, and V3, ground port electrode pads corresponding to the ground ports G1, G2, and G3, and output port electrode pads corresponding to the output ports E1, E2, and E3. These electrode pads and the MR elements 11 and 12 are electrically connected by the wiring portions 60.

Next, an example of the configuration of the layered films 50 in each of the MR elements 11 and 12 will be described with reference to FIG. 8. FIG. 8 is a perspective view showing a layered film 50. In this example, the layered film 50 includes a magnetization pinned layer 52 having a magnetization of a predetermined direction, a free layer 54 having a magnetization whose direction is variable depending on the target magnetic field MF, a gap layer 53 located between the magnetization pinned layer 52 and the free layer 54, and an antiferromagnetic layer 51. The antiferromagnetic layer 51, the magnetization pinned layer 52, the gap layer 53, and the free layer 54 are stacked in this order. The antiferromagnetic layer 51 is formed of an antiferromagnetic material and is in exchange coupling with the magnetization pinned layer 52 to thereby pin the direction of the magnetization of the magnetization pinned layer 52.

Each of the MR elements 11 and 12 may be a tunnel magnetoresistive (TMR) element, or a current-perpendicular-to-plane (CPP) giant magnetoresistive (GMR) element where a sense current for use in magnetic signal detection is fed in a direction substantially perpendicular to the plane of each layer constituting the layered film 50. In the TMR element, the gap layer 53 is a tunnel barrier layer. In the GMR element, the gap layer 53 is a nonmagnetic conductive layer.

The resistance of the layered film 50 changes depending on the angle that the direction of the magnetization of the free layer 54 forms with the direction of the magnetization of the magnetization pinned layer 52. The resistance has a minimum value when the angle is 0°, and a maximum value when the foregoing angle is 180°. Each of the MR elements 11 and 12 has sensitivity in a direction parallel to the direction of the magnetization of the magnetization pinned layer 52.

In the example embodiment, the magnetization of the magnetization pinned layer 52 includes a component in the direction parallel to the X direction. In the example embodiment, the magnetization of the magnetization pinned layer 52 in the MR element 11 and the magnetization of the magnetization pinned layer 52 in the MR element 12 include components in the same direction.

If the magnetization of the magnetization pinned layer 52 includes a component in a specific direction, the component in the specific direction may be the main component of the magnetization of the magnetization pinned layer 52. Alternatively, the magnetization of the magnetization pinned layer 52 may be free of a component in a direction orthogonal to the specific direction. In the example embodiment, if the magnetization of the magnetization pinned layer 52 includes a component in the specific direction, the direction of the magnetization of the magnetization pinned layer 52 is the same or substantially the same as the specific direction.

In the example embodiment, each of the plurality of layered films 50 has a shape long in the direction parallel to the Y direction. This gives the free layer 54 in each of the plurality of layered films 50 a shape anisotropy such that the direction of the magnetization easy axis is parallel to the Y direction. When there is no magnetic field applied, the direction of the magnetization of the free layer 54 is thus parallel to the Y direction. When there is a magnetic field component in the direction parallel to the X direction, the direction of the magnetization of the free layer 54 changes depending on the direction and strength of the magnetic field component. The angle that the direction of the magnetization of the free layer 54 forms with the direction of the magnetization of the magnetization pinned layer 52 thus changes depending on the direction and strength of the magnetic field component received by each of the plurality of layered films 50. Each of the plurality of layered films 50 thus has a resistance corresponding to the output magnetic field component. The direction of the magnetization easy axis can be set to the direction parallel to the Y direction regardless of the shape anisotropy by providing a magnet for applying a bias magnetic field to the free layer 54 of the layered film 50.

The magnetization pinned layer 52 may be a so-called self-pinned layer (Synthetic Ferri Pinned layer, SFP layer). The self-pinned layer has a stacked ferri structure in which a ferromagnetic layer, a nonmagnetic intermediate layer, and a ferromagnetic layer are stacked, and the two ferromagnetic layers are antiferromagnetically coupled. In a case where the magnetization pinned layer 52 is the self-pinned layer, the antiferromagnetic layer 51 may be omitted.

The following description will be given by using an example case where the magnetization of the magnetization pinned layer 52 in the MR element 11 and the magnetization of the magnetization pinned layer 52 in the MR element 12 include a component in the −X direction. When there is no target magnetic field MF and therefore no magnetic field component generated by the plurality of yokes 21, the direction of the magnetization of the free layer 54 of the layered film 50 is parallel to the Y direction. If the direction of the target magnetic field MF applied to the plurality of yokes 21 is the Z direction, the direction of the magnetic field component that the plurality of layered films 50 of the MR element 11 receive is the −X direction, and the direction of the magnetic field component that the plurality of layered films 50 of the MR element 12 receive is the X direction. In such a case, the direction of the magnetization of the free layer 54 in each of the plurality of layered films 50 of the MR element 11 tilts from the direction parallel to the Y direction toward the −X direction, and the direction of the magnetization of the free layer 54 in each of the plurality of layered films 50 of the MR element 12 tilts from the direction parallel to the Y direction toward the X direction. As a result, the resistance of each of the plurality of layered films 50 of the MR element 11 decreases and the resistance of each of the plurality of layered films 50 of the MR element 12 increases compared to when there is no magnetic field component. As a result, the resistance of the MR element 11 decreases and the resistance of the MR element 12 increases.

If the direction of the target magnetic field MF applied to the plurality of yokes 21 is the −Z direction, the directions of the magnetic field components and the changes in the resistances of the respective MR elements 11 and 12 are opposite to those in the foregoing case where the direction of the target magnetic field MF is the Z direction.

The amount of change in the resistance of each of the MR elements 11 and 12 depends on the strength of the magnetic field component that each of the plurality of layered films 50 receives. As the strength of the magnetic field component increases, the resistance of each of the MR elements 11 and 12 changes so that the amount of increase or the amount of decrease increases. As the strength of the magnetic field component decreases, the resistance of each of the MR elements 11 and 12 changes so that the amount of increase or the amount of decrease decreases. The strength of the magnetic field component depends on the strength of the component of the target magnetic field MF applied to the plurality of yokes 21 in the direction parallel to the Z direction.

As has been described above, when the direction and strength of the target magnetic field MF applied to the plurality of yokes 21 change, the resistance of each of the MR elements 11 and 12 changes so that the resistance of the MR element 11 increases and the resistance of the MR element 12 decreases, or so that the resistance of the MR element 11 decreases and the resistance of the MR element 12 increases. Consequently, the potential at the connection point of the MR elements 11 and 12 changes. This potential changes with the angle that the direction of the magnetization of the free layer 54 forms with the direction of the magnetization of the magnetization pinned layer 52.

The first detection circuit 10a generates a signal corresponding to the potential at the output port E1 connected to the connection point of the MR elements 11a and 12a as the first detection signal S1. The second detection circuit 10b generates a signal corresponding to the potential at the output port E2 connected to the connection point of the MR elements 11b and 12b as the second detection signal S2. The third detection circuit 10c generates a signal corresponding to the potential at the output port E3 connected to the connection point of the MR elements 11c and 12c as the third detection signal S3.

Next, a relationship between the reference coordinate system shown in FIGS. 1, 2, and 4 and the orthogonal coordinate system shown in FIGS. 5 to 8 will be described. The orthogonal coordinate system shown in FIGS. 5 to 8 is defined for each of the first to third electronic components 1a to 1c. For the first electronic component 1a, the Y direction of the orthogonal coordinate system agrees with the U direction of the reference coordinate system, and the X direction of the orthogonal coordinate system agrees with a direction 90° rotated from the U direction of the reference coordinate system toward the W direction of the reference coordinate system. For the second electronic component 1b, the Y direction of the orthogonal coordinate system agrees with the V direction of the reference coordinate system, and the X direction of the orthogonal coordinate system agrees with a direction 90° rotated from the V direction of the reference coordinate system toward the U direction of the reference coordinate system. For the third electronic component 1c, the Y direction of the orthogonal coordinate system agrees with the W direction of the reference coordinate system, and the X direction of the orthogonal coordinate system agrees with a direction 90° rotated from the W direction of the reference coordinate system toward the V direction of the reference coordinate system.

In FIG. 4, the MR elements 11a, 11b, 11c, 12a, 12b, and 12c are schematically shown by a figure representing a layered film 50 each. In the first detection circuit 10a of the first electronic component 1a, each of the plurality of layered films 50 has a shape long in a direction parallel to the U direction. In the second detection circuit 10b of the second electronic component 1b, each of the plurality of layered films 50 has a shape long in a direction parallel to the V direction. In the third detection circuit 10c of the third electronic component 1c, each of the plurality of layered films 50 has a shape long in a direction parallel to the W direction.

In FIG. 4, the first to third structural bodies 20a to 20c are schematically shown by a figure representing a yoke 21 each. In the first structural body 20a of the first electronic component 1a, each of the plurality of yokes 21 has a shape long in the direction parallel to the U direction. In the second structural body 20b of the second electronic component 1b, each of the plurality of yokes 21 has a shape long in the direction parallel to the V direction. In the third structural body 20c of the third electronic component 1c, each of the plurality of yokes 21 has a shape long in the direction parallel to the W direction.

Next, a method for generating the angle detection value θs will be described with reference to FIG. 4. The following description includes a description of the operation of the processor 40. In the example embodiment, the phase of the periodic component of the second detection signal S2 is 120° different from that of the periodic component of the first detection signal S1. The phase of the periodic component of the third detection signal S3 is 120° different from that of the periodic component of the second detection signal S2. The phase of the periodic component of the third detection signal S3 is 240° different from that of the periodic component of the first detection signal S1.

The first signal Sa output from the differential detector 31, the second signal Sb output from the differential detector 32, and the third signal Sc output from the differential detector 33 are expressed by the following Eqs. (1), (2), and (3), respectively:

$$Sa = S 1 - S 2 , \qquad ( 1 )$$

$$Sb = S 2 - S 3 , and \qquad ( 2 )$$

$$Sc = S 3 - S 1. \qquad ( 3 )$$

The first signal Sa is equivalent to a difference between the first detection signal S1 and the second detection signal S2. The second signal Sb is equivalent to a difference between the second detection signal S2 and the third detection signal S3. The third signal Sc is equivalent to a difference between the third detection signal S3 and the first detection signal S1. The processor 40 is configured to generate the angle detection value θs using the first to third signals Sa to Sc. For example, the processor 40 calculates θs within the range of 0° or more and less than 360° by using the following

Eq. (4):

$$θ s = atan ( \frac{\sqrt{3} Sa}{Sc - Sb} ) \qquad ( 4 )$$

Here, “atan” represents an arctangent.

Next, a method for manufacturing the magnetic sensor 1 according to the example embodiment will be briefly described. The method for manufacturing the magnetic sensor 1 includes a step of forming a detection circuit 10, a step of forming a structural body 20, and a step of forming a shield 22. The step of forming the detection circuit 10 includes a step of forming the MR elements 11 and 12, and a step of forming the wiring portions 60. The step of forming the MR elements 11 and 12 includes a step of forming the plurality of layered films 50.

In the step of forming the plurality of layered films 50, a plurality of initial layered films to later become the plurality of layered films 50 are initially formed. Each of the plurality of initial layered films includes at least an initial magnetization pinned layer to later become a magnetization pinned layer 52, and a free layer 54 and a gap layer 53.

Next, the direction of the magnetization of the initial magnetization pinned layers is fixed to a predetermined direction using laser light and an external magnetic field in the predetermined direction. In particular, in the example embodiment, the plurality of initial layered films to later become the plurality of layered films 50 of the MR element 11 and the plurality of initial layered films to later become the plurality of layered films 50 of the MR element 12 are both irradiated with the laser light while an external magnetic field in the same direction (for example, −X direction) is applied thereto. When the irradiation with the laser light is completed, the direction of the magnetization of the initial magnetization pinned layers is fixed to the predetermined direction. The initial magnetization pinned layers thereby become the magnetization pinned layers 52, and the plurality of initial layered films become the plurality of layered films 50.

The step of forming the detection circuit 10 and the step of forming the structural body 20 may be performed with respect to each of the first to third electronic components 1a to 1c. More specifically, the method for manufacturing the magnetic sensor 1 may include a step of forming the first detection circuit 10a and the first structural body 20a, a step of forming the second detection circuit 10b and the second structural body 20b, and a step of forming the third detection circuit 10c and the third structural body 20c.

Next, the operation and effects of the magnetic sensor 1, the magnetic sensor device 2, and the magnetic sensor system 100 according to the example embodiment will be described. A noise magnetic field other than the target magnetic field MF is in some cases applied to the magnetic sensor 1 aside from the target magnetic field MF. Suppose now that a noise magnetic field in the Z or −Z direction is applied to the magnetic sensor 1. In such a case, the resistance of each of the plurality of layered films 50 of the MR element 11 decreases and that of each of the plurality of layered films 50 of the MR element 12 increases, or the resistance of each of the plurality of layered films 50 of the MR element 11 increases and that of each of the plurality of layered films 50 of the MR element 12 decreases, compared to when there is no noise magnetic field. As a result, the potential at the connection point of the MR elements 11 and 12 increases or decreases compared to when there is no noise magnetic field.

In the example embodiment, the amounts of change in the potentials of the respective connection points in the first to third detection circuits 10a to 10c due to the noise magnetic field are the same or substantially the same. The amount of change in the potential of the connection point in each of the first to third detection circuits 10a to 10c will be denoted by S_{off}. In the presence of the noise magnetic field, the first detection signal is expressed as S1+S_{off}, the second detection signal as S2+S_{off}, and the third detection signal as S3+S_{off}. If the angle detection value θs is generated using the first to third detection signals S1 to S3 without generating the first to third signals Sa to Sc, the amounts of change S_{off} are not cancelled out and an error due to the noise magnetic field occurs in the angle detection value θs.

By contrast, according to the example embodiment, the processor 40 generates the angle detection value θs by performing a calculation using the first to third detection signals S1 to S3 so that an error in the angle detection value θs due to the noise magnetic field is reduced compared to the case where the angle detection value θs is generated without generating at least one signal equivalent to a difference between two of the first to third detection signals S1 to S3. In other words, in the example embodiment, the amounts of change S_{off} are cancelled out in generating the first to third signals Sa to Sc as can be seen from Eqs. (1) to (3). According to the example embodiment, the effect of the noise magnetic field can thereby be reduced. As a result, according to the example embodiment, an error occurring in the angle detection value θs due to the noise magnetic field can be reduced.

According to the example embodiment, the noise magnetic field in a direction orthogonal to the Z direction can be reduced by the shield 22 shown in FIG. 7. According to the example embodiment, the effect of the noise magnetic field can thus also be reduced.

### Second Example Embodiment

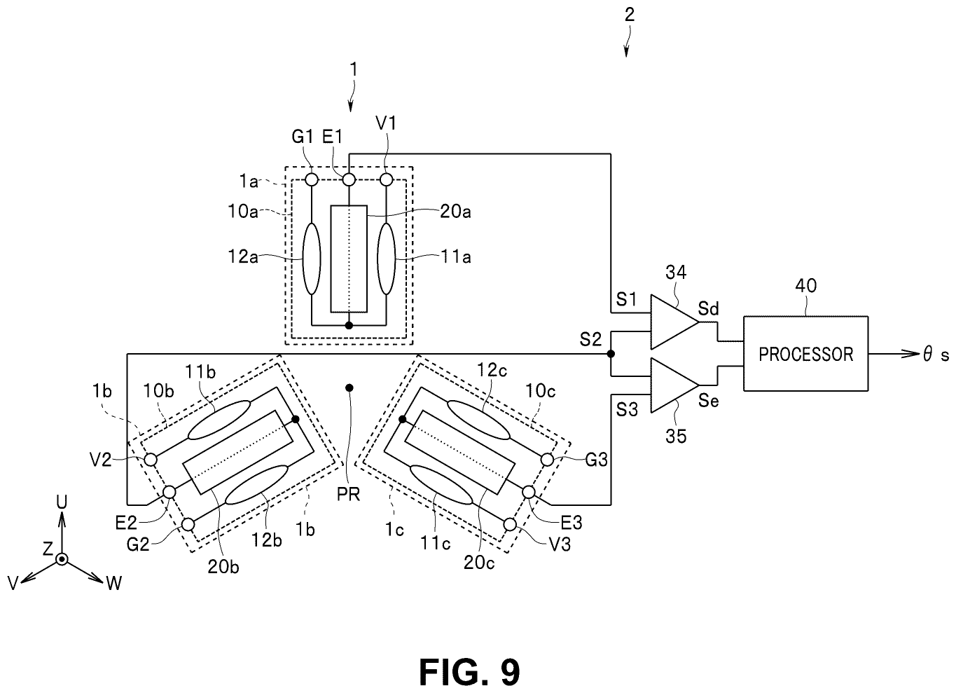

Next, a magnetic sensor device 2 according to a second example embodiment of the technology will be described with reference to FIG. 9. FIG. 9 is a circuit diagram showing a configuration of the magnetic sensor device 2 according to the example embodiment.

The magnetic sensor device 2 according to the example embodiment includes differential detectors 34 and 35 instead of the differential detectors 31, 32, and 33 in the first example embodiment. The differential detector 34 outputs a signal corresponding to a potential difference between the output port E1 of the first detection circuit 10a and the output port E2 of the second detection circuit 10b as a first signal Sd. The differential detector 35 outputs a signal corresponding to a potential difference between the output port E2 of the second detection circuit 10b and the output port E3 of the third detection circuit 10c as a second signal Se. Each of the differential detectors 34 and 35 has the same configuration as that of each of the differential detectors 31 to 33. The first and second signals Sd and Se may be generated by digital signal processing or by analog signal processing.

The first and second signals Sd and Se are expressed by the following Eqs. (5) and (6), respectively:

$$Sd = S 1 - S 2 , and \qquad ( 5 )$$

$$Se = S 2 - S 3. \qquad ( 6 )$$

The first signal Sd is equivalent to a difference between the first detection signal S1 and the second detection signal S2. The second signal Se is equivalent to a difference between the second detection signal S2 and the third detection signal S3. The processor 40 is configured to generate a first calculated signal by a calculation including determination of a difference between the first signal Sd and the second signal Se, generate a second calculated signal by a calculation including determination of a sum of the first signal Sd and the second signal Se, and generate the angle detection value θs using the first and second calculated signals.

For example, the processor 40 generates the angle detection value θs in the following manner. The processor 40 initially calculates a maximum value max (Sd-Se) of the difference between the first and second signals Sd and Se and a minimum value min (Sd-Se) of the difference between the first and second signals Sd and Se. The processor 40 then calculates a correction value Bf using the maximum value max (Sd-Se) and the minimum value min (Sd-Se) by the following Eq. (7):

$$B f = ( max ( S d - S e ) - min ( S d - S e ) ) / 2. \qquad ( 7 )$$

The processor 40 also calculates a maximum value max (Sd+Se) of the sum of the first and second signals Sd and Se and a minimum value min (Sd+Se) of the sum of the first and second signals Sd and Se. The processor 40 then calculates a correction value Bg using the maximum value max (Sd+Se) and the minimum value min (Sd+Se) by the following Eq. (8):

$$Bg = ( max ( S d + S e ) - min ( S d + S e ) ) / 2. \qquad ( 8 )$$

Next, the processor 40 calculates a first calculated signal Sf using the following Eq. (9), and calculates a second calculated signal Sg using the following Eq. (10):

$$S f = ( S d - Se ) / Bf , and \qquad ( 9 )$$

$$Sg = ( Sd + Se ) / Bg . \qquad ( 10 )$$

The processor 40 then calculates θs within the range of 0° or more and less than 360° using the following Eq. (11):

$$θ s = atan ( Sf / Sg ) . \qquad ( 11 )$$

Next, the operation and effects of the magnetic sensor 1 and the magnetic sensor device 2 according to the example embodiment will be described. If a noise magnetic field in the Z or −Z direction is applied to the magnetic sensor 1, the potential at the connection point of the MR elements 11 and 12 in each of the first to third detection circuits 10a to 10c changes as in the first example embodiment. Like the first example embodiment, the amount of change in the potential at the connection point of the MR elements 11 and 12 in each of the first to third detection circuits 10a to 10c will be denoted by S_{off}. As can be seen from Eqs. (5) and (6), the amounts of change S_{off} are cancelled out in generating the first and second detection signals Sd and Se. According to the example embodiment, the effect of the noise magnetic field can thus be reduced.

In the example embodiment, the number of differential detectors (two) is smaller than the number of detection circuits (three). According to the example embodiment, the configuration of the magnetic sensor device 2 can thus be simplified.

The configuration, operation, and effects of the present example embodiment are otherwise the same as those of the first example embodiment.

### Third Example Embodiment

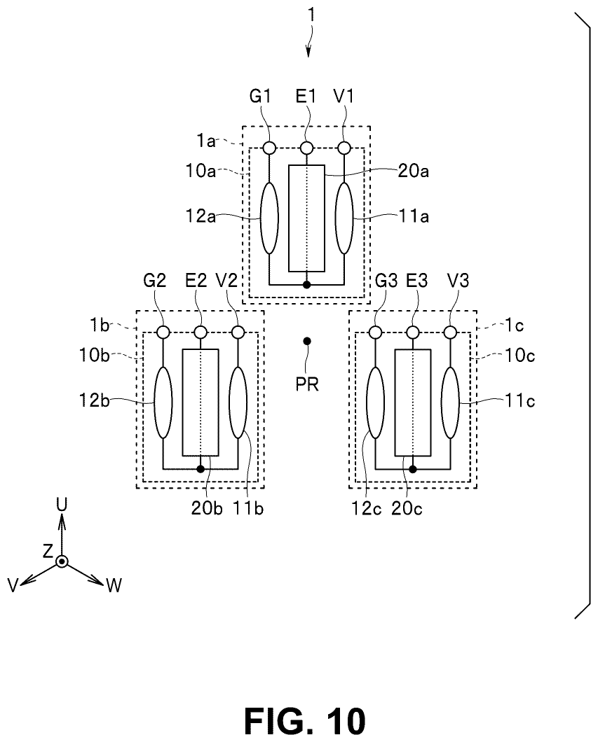

Next, a magnetic sensor 1 according to a third example embodiment of the technology will be described with reference to FIG. 10. FIG. 10 is a circuit diagram schematically showing a configuration of the magnetic sensor 1 according to the example embodiment.

In the example embodiment, each of the second and third electronic components 1b and 1c is in the same orientation as that of the first electronic component 1a. More specifically, in the example embodiment, for all the first to third electronic components 1a to 1c, the Y direction of the orthogonal coordinate system (see FIGS. 5 to 8) agrees with the U direction of the reference coordinate system, and the X direction of the orthogonal coordinate system (see FIGS. 5 to 8) agrees with a direction 90° rotated from the U direction of the reference coordinate system toward the W direction of the reference coordinate system.

In the example embodiment, in all the first detection circuit 10a of the first electronic component 1a, the second detection circuit 10b of the second electronic component 1b, and the third detection circuit 10c of the third electronic component 1c, each of the plurality of layered films 50 (see FIGS. 5 to 8) has a shape long in the direction parallel to the U direction.

In the example embodiment, in all the first structural body 20a of the first electronic component 1a, the second structural body 20b of the second electronic component 1b, and the third structural body 20c of the third electronic component 1c, each of the plurality of yokes 21 (see FIGS. 5 to 7) has a shape long in the direction parallel to the U direction.

A method for generating the angle detection value θs in the example embodiment may be the same as that of the first example embodiment or that of the second example embodiment. As can be seen from the present example embodiment and the first example embodiment, the technology can generate the angle detection value θs regardless of the relationship between the X and Y directions of the orthogonal coordinate system and the U, V, and W directions of the reference coordinate system, or equivalently, the orientation of each of the second and third electronic components 1b and 1c. Similarly, the angle detection value θs can be generated even if the orientation of the first electronic component 1a is different from that in the first or second example embodiment. According to the technology, the angle detection value θs can thus be generated regardless of the orientation of each of the first to third electronic components 1a to 1c.

The configuration, operation, and effects of the present example embodiment are otherwise the same as those of the first or second example embodiment.

### Fourth Example Embodiment

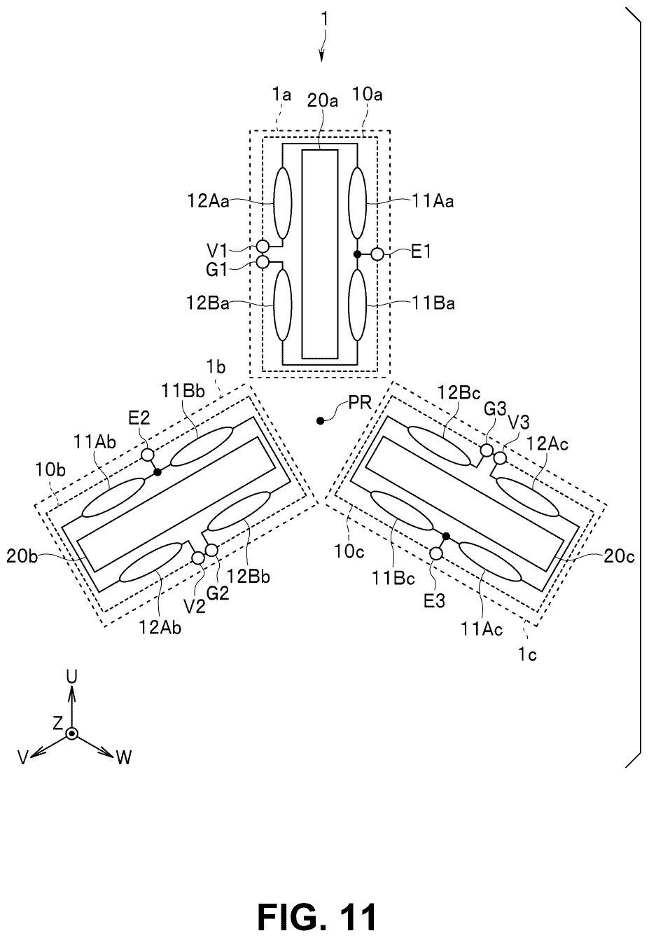

Next, a magnetic sensor 1 according to a fourth example embodiment of the technology will be described with reference to FIG. 11. FIG. 11 is a circuit diagram schematically showing a configuration of the magnetic sensor 1 according to the example embodiment. In the example embodiment, the plurality of MR elements included in each of the first to third electronic components 1a to 1c of the magnetic sensor 1 have a configuration different from that in the first example embodiment.

In the example embodiment, the first detection circuit 10a of the first electronic component 1a includes four MR elements 11Aa, 11Ba, 12Aa, and 12Ba instead of the two MR elements 11a and 12a in the first example embodiment. The MR elements 11Aa and 12Aa are provided between the power supply port V1 and the output port E1 in the circuit configuration and connected in series. The MR elements 11Ba and 12Ba are provided between the ground port G1 and the output port E1 in the circuit configuration and connected in series.

In the example embodiment, the second detection circuit 10b of the second electronic component 1b includes four MR elements 11Ab, 11Bb, 12Ab, and 12Bb instead of the two MR elements 11b and 12b in the first example embodiment. The MR elements 11Ab and 12Ab are provided between the power supply port V2 and the output port E2 in the circuit configuration and connected in series. The MR elements 11Bb and 12Bb are provided between the ground port G2 and the output port E2 in the circuit configuration and connected in series.

In the example embodiment, the third detection circuit 10c of the third electronic component 1c includes four MR elements 11Ac, 11Bc, 12Ac, and 12Bc instead of the two MR elements 11c and 12c in the first example embodiment. The MR elements 11Ac and 12Ac are provided between the power supply port V3 and the output port E3 in the circuit configuration and connected in series. The MR elements 11Bc and 12Bc are provided between the ground port G3 and the output port E3 in the circuit configuration and connected in series.

Each of the MR elements 11Aa to 11Ac and 11Ba to 11Bc has the same configuration and the same positional relationship with the structural body 20 as those of the MR element 11 in the first example embodiment. The description of the MR element 11 in the first example embodiment applies to the MR elements 11Aa to 11Ac and 11Ba to 11Bc except for the direction of the magnetization of the magnetization pinned layer 52 (see FIG. 8). Each of the MR elements 12Aa to 12Ac and 12Ba to 12Bc has the same configuration and the same positional relationship with the structural body 20 as those of the MR element 12 in the first example embodiment. The description of the MR element 12 in the first example embodiment applies to the MR elements 12Aa to 12Ac and 12Ba to 12Bc except for the direction of the magnetization of the magnetization pinned layer 52.

In the example embodiment, the magnetization of the magnetization pinned layer 52 in the MR element 11Aa and the magnetization of the magnetization pinned layer 52 in the MR element 12Ba include components in the same direction. The magnetization of the magnetization pinned layer 52 in the MR element 11Ba and the magnetization of the magnetization pinned layer 52 in the MR element 12Aa include components in the same direction. The magnetization of the magnetization pinned layer 52 in the MR element 11Aa and the magnetization of the magnetization pinned layer 52 in the MR element 12Aa include components in opposite directions. The magnetization of the magnetization pinned layer 52 in the MR element 11Ba and the magnetization of the magnetization pinned layer 52 in the MR element 12Ba include components in opposite directions.

Now, an example of the directions of the magnetizations of the magnetization pinned layers 52 in the MR elements 11Aa, 11Ba, 12Aa, and 12Ba will be described with reference to the orthogonal coordinate system in the first example embodiment, shown in FIGS. 5 to 7. The magnetization of the magnetization pinned layer 52 in the MR element 11Aa and the magnetization of the magnetization pinned layer 52 in the MR element 12Ba include components in the X direction. The magnetization of the magnetization pinned layer 52 in the MR element 11Ba and the magnetization of the magnetization pinned layer 52 in the MR element 12Aa include components in the −X direction.

If the direction of the target magnetic field MF applied to the plurality of yokes 21 (see FIGS. 5 to 7) of the first structural body 20a of the first electronic component 1a is the Z direction, the direction of the magnetic field component that the plurality of layered films 50 (see FIGS. 5 to 7) of the MR elements 11Aa and 11Ba receive is the −X direction, and the direction of the magnetic field component that the plurality of layered films 50 of the MR elements 12Aa and 12Ba receive is the X direction. In such a case, the direction of the magnetization of the free layer 54 in each of the plurality of layered films 50 of the MR elements 11Aa and 11Ba tilts from the direction parallel to the Y direction toward the −X direction. The direction of the magnetization of the free layer 54 in each of the plurality of layered films 50 of the MR elements 12Aa and 12Ba tilts from the direction parallel to the Y direction toward the X direction. As a result, the resistance of each of the plurality of layered films 50 of the MR elements 11Aa and 12Aa increases, and the resistance of each of the plurality of layered films 50 of the MR elements 11Ba and 12Ba decreases, compared to when there is no magnetic field component. Consequently, the resistances of the MR elements 11Aa and 12Aa increase, and the resistances of the MR elements 11Ba and 12Ba decrease.

If the direction of the target magnetic field MF applied to the plurality of yokes 21 is the −Z direction, the directions of the magnetic field components and the changes in the resistances of the respective MR elements 11Aa, 11Ba, 12Aa, and 12Ba are opposite to those in the foregoing case where the direction of the target magnetic field MF is the Z direction.

The amount of change in the resistance of each of the MR elements 11Aa, 11Ba, 12Aa, and 12Ba depends on the strength of the magnetic field component that each of the plurality of layered films 50 receives. As the strength of the magnetic field component increases, the resistance of each of the MR elements 11Aa, 11Ba, 12Aa, and 12Ba changes so that the amount of increase or the amount of decrease increases. As the strength of the magnetic field component decreases, the resistance of each of the MR elements 11Aa, 11Ba, 12Aa, and 12Ba changes so that the amount of increase or the amount of decrease decreases. The strength of the magnetic field component depends on the strength of the component of the target magnetic field MF applied to the plurality of yokes 21 in the direction parallel to the Z direction.

As described above, when the direction and strength of the target magnetic field MF applied to the plurality of yokes 21 change, the resistance of each of the MR elements 11Aa, 11Ba, 12Aa, and 12Ba changes so that the resistances of the MR elements 11Aa and 12Aa increase and the resistances of the MR elements 11Ba and 12Ba decrease, or so that the resistances of the MR elements 11Aa and 12Aa decrease and the resistances of the MR elements 11Ba and 12Ba increase. As a result, the potential at the connection point of the pair of MR elements 11Aa and 12Aa connected in series and the pair of MR elements 11Ba and 12Ba connected in series changes. This potential changes with the angle that the direction of the magnetization of the free layer 54 forms with the direction of the magnetization of the magnetization pinned layer 52.

The foregoing description of the characteristics related to the MR elements 11Aa, 11Ba, 12Aa, and 12Ba also applies to the group of MR elements 11Ab, 11Bb, 12Ab, and 12Bb and the group of MR elements 11Ac, 11Bc, 12Ac, and 12Bc. A description of the characteristics related to the MR elements 11Ab, 11Bb, 12Ab, and 12Bb is given by replacing the first electronic component 1a, the first structural body 20a, and the MR elements 11Aa, 11Ba, 12Aa, and 12Ba in the foregoing description of the characteristics related to the MR elements 11Aa, 11Ba, 12Aa, and 12Ba with the second electronic component 1b, the second structural body 20b, and the MR elements 11Ab, 11Bb, 12Ab, and 12Bb, respectively. A description of the characteristics related to the MR elements 11Ac, 11Bc, 12Ac, and 12Bc is given by replacing the first electronic component 1a, the first structural body 20a, and the MR elements 11Aa, 11Ba, 12Aa, and 12Ba in the foregoing description of the characteristics related to the MR elements 11Aa, 11Ba, 12Aa, and 12Ba with the third electronic component 1c, the third structural body 20c, and the MR elements 11Ac, 11Bc, 12Ac, and 12Bc, respectively.

In the example embodiment, the first detection circuit 10a generates a signal corresponding to the potential at the output port E1 connected to the connection point of the pair of MR elements 11Aa and 12Aa connected in series and the pair of MR elements 11Ba and 12Ba connected in series as the first detection signal S1. The second detection circuit 10b generates a signal corresponding to the potential at the output port E2 connected to the connection point of the pair of MR elements 11Ab and 12Ab connected in series and the pair of MR elements 11Bb and 12Bb connected in series as the second detection signal S2. The third detection circuit 10c generates a signal corresponding to the potential at the output port E3 connected to the connection point of the pair of MR elements 11Ac and 12Ac connected in series and the pair of MR elements 11Bc and 12Bc connected in series as the third detection signal S3.

A method for generating the angle detection value θs in the example embodiment may be the same as that of the first example embodiment or that of the second example embodiment. The orientation of each of the second and third electronic components 1b and 1c in the example embodiment may be the same as that in the first example embodiment or that in the third example embodiment. The configuration, operation, and effects of the present example embodiment are otherwise the same as those of any of the first to third example embodiments.

### Fifth Example Embodiment

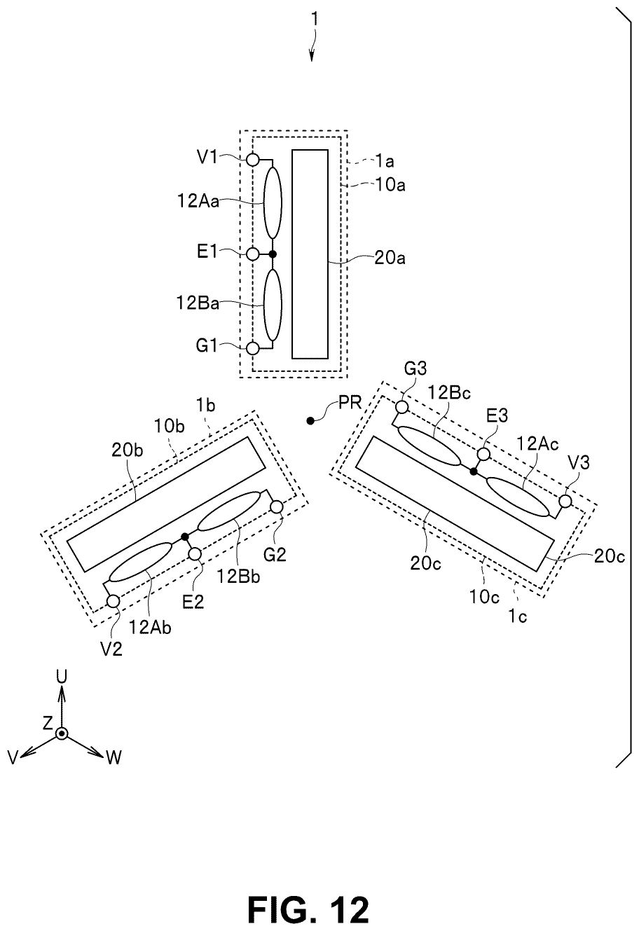

Next, a magnetic sensor 1 according to a fifth example embodiment of the technology will be described with reference to FIG. 12. FIG. 12 is a circuit diagram schematically showing a configuration of the magnetic sensor 1 according to the example embodiment. The present example embodiment differs from the fourth example embodiment in the configuration of the plurality of MR elements included in each of the first to third electronic components 1a to 1c of the magnetic sensor 1.

In the example embodiment, the first detection circuit 10a of the first electronic component 1a does not include the two MR elements 11Aa and 11Ba in the fourth example embodiment. The connection point of the MR elements 12Aa and 12Ba is connected to the output port E1. The first detection circuit 10a generates a signal corresponding to the potential at the output port E1 as the first detection signal S1.

In the example embodiment, the second detection circuit 10b of the second electronic component 1b does not include the two MR elements 11Ab and 11Bb in the fourth example embodiment. The connection point of the MR elements 12Ab and 12Bb is connected to the output port E2. The second detection circuit 10b generates a signal corresponding to the potential at the output port E2 as the second detection signal S2.

In the example embodiment, the third detection circuit 10c of the third electronic component 1c does not include the two MR elements 11Ac and 11Bc in the fourth example embodiment. The connection point of the MR elements 12Ac and 12Bc is connected to the output port E3. The third detection circuit 10c generates a signal corresponding to the potential at the output port E3 as the third detection signal S3.

The configuration, operation, and effects of the present example embodiment are otherwise the same as those of the fourth example embodiment.

### Sixth Example Embodiment

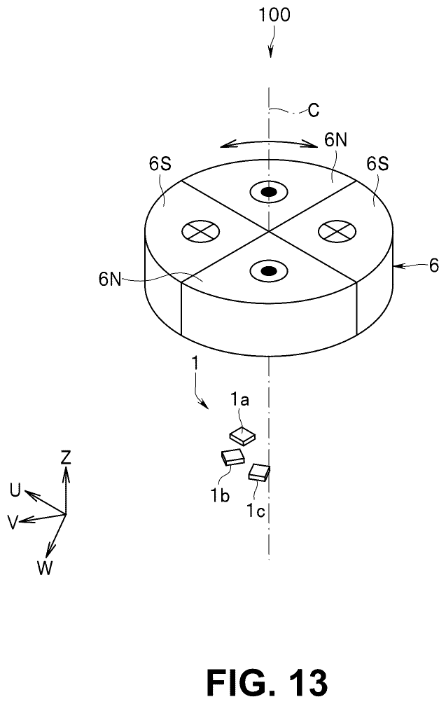

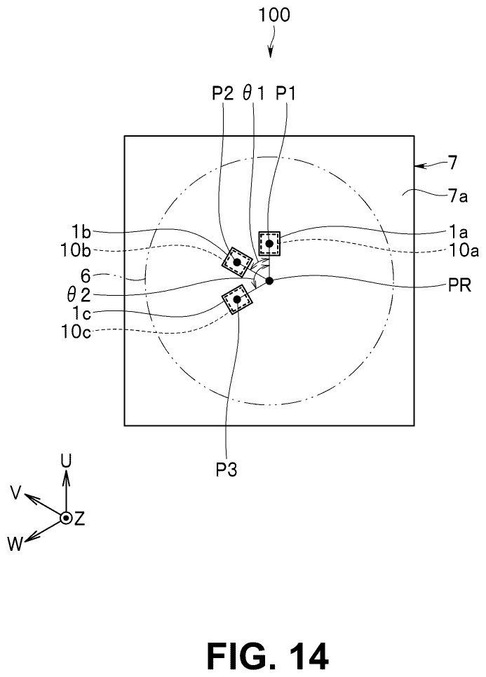

Next, a magnetic sensor system 100 according to a sixth example embodiment of the technology will be described with reference to FIGS. 13 and 14. FIG. 13 is a perspective view showing the magnetic sensor system 100 according to the example embodiment. FIG. 14 is a plan view showing the magnetic sensor system 100 according to the example embodiment.

The magnetic sensor system 100 according to the example embodiment includes a magnetic field generator 6 that generates the target magnetic field MF instead of the magnetic field generator 5 in the first example embodiment. The magnetic field generator 6 is a cylindrical magnet. The magnetic field generator 6 includes two N poles 6N and two S poles 6S. The N poles 6N and the S poles 6S are circumferentially alternately arranged about the center axis of the cylinder.

The N poles 6N have a magnetization in one direction parallel to a reference axis C. The S poles 6S have a magnetization in the direction opposite to that of the magnetization of the N poles 6N. FIG. 13 shows the direction of the magnetization of the N poles 6N as an upward direction, and the direction of the magnetization of the S poles 6S as a downward direction.

In the example embodiment, the strength of the target magnetic field MF at a specific position changes periodically with the rotation of the magnetic field generator 6. In particular, in the example embodiment, the strength of the target magnetic field MF at a specific position changes by two periods as the magnetic field generator 6 rotates one revolution.

The first to third detection circuits 10a to 10c, i.e., the first to third electronic components 1a to 1c are disposed to oppose to one end surface of the magnetic field generator 6, i.e., the cylindrical magnet.

As shown in FIG. 14, the second position P2 is a position rotated from the first position P1 by an angle θ1 circumferentially about the reference axis C. The third position P3 is a position rotated from the first position P1 by an angle θ2 circumferentially about the reference axis C. As described in the first example embodiment, the angle θ1 is equivalent to an electrical angle of (120+360×m)°. The angle θ2 is equivalent to an electrical angle of (240+360×n)°.

The number of pairs of N and S poles 6N and 6S of the magnetic field generator 6 is k. The angle θ1 is (120/k+360×m/k)°. The angle θ2 is (240/k+360×n/k)°.

In the example embodiment, m and n are both 0, and k is 2. The second position P2 is thus a position rotated from the first position P1 by 60° circumferentially about the reference axis C (counterclockwise in FIG. 14). The third position P3 is a position rotated from the first position P1 by 120° circumferentially about the reference axis C (counterclockwise in FIG. 2). In the example embodiment, the physical angle equivalent to the electrical angle of 120° is 60°. The physical angle equivalent to the electrical angle of 240° is 120°.

As described in the first example embodiment, the U direction is a direction orthogonal to the Z direction and from the reference axis C toward the first position P1. The V direction is a direction orthogonal to the Z direction and from the reference axis C toward the second position P2. The W direction is a direction orthogonal to the Z direction and from the reference axis C toward the third position P3. In the example embodiment, the V direction is a direction rotated from the U direction by 60° counterclockwise in FIG. 14. The W direction is a direction rotated from the V direction by 60° counterclockwise in FIG. 14 and rotated from the U direction by 120° counterclockwise in FIG. 14.

The configuration of the first to third electronic components 1a to 1c in the example embodiment may be the same as that of any of the first, third, and fifth example embodiments. A method for generating the angle detection value θs in the example embodiment may be the same as that of the first example embodiment or that of the second example embodiment. The configuration, operation, and effects of the present example embodiment are otherwise the same as those of any of the first to fifth example embodiments.

### Seventh Example Embodiment

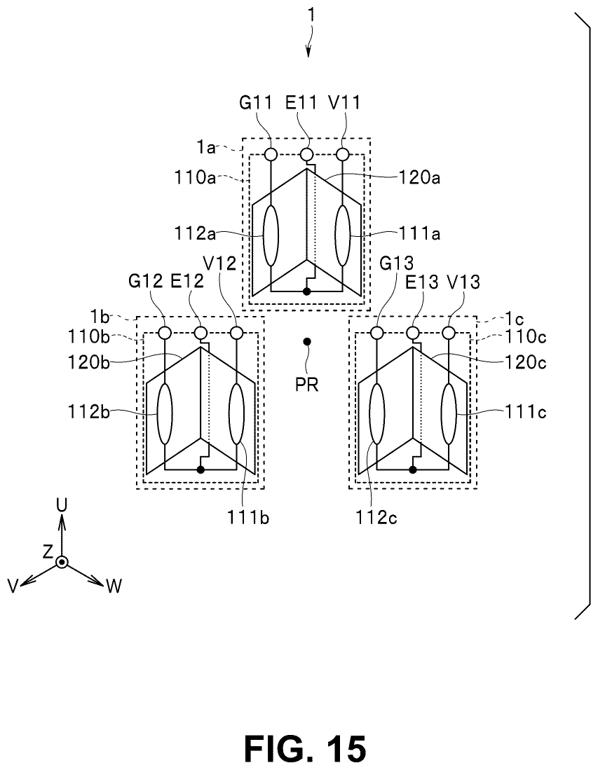

Next, a magnetic sensor 1 according to a seventh example embodiment of the technology will be described with reference to FIG. 15. FIG. 15 is a circuit diagram schematically showing a configuration of the magnetic sensor 1 according to the example embodiment.

The magnetic sensor 1 according to the example embodiment includes a first detection circuit 110a, a second detection circuit 110b, a third detection circuit 110c, a first structural body 120a, a second structural body 120b, and a third structural body 120c instead of the first to third detection circuit 10a to 10c and the first to third structural bodies 20a to 20c in the first example embodiment.

In the present example embodiment, the first electronic component 1a includes the first detection circuit 110a and the first structural body 120a. The second electronic component 1b includes the second detection circuit 110b and the second structural body 120b. The third electronic component 1c includes the third detection circuit 110c and the third structural body 120c.

The arrangement of the first to third electronic components 1a to 1c is the same as that of the first to third electronic components 1a to 1c in the first example embodiment. More specifically, the first electronic component 1a is disposed in an area including the first position P1 shown in FIGS. 1 and 2. The second electronic component 1b is disposed in an area including the second position P2 shown in FIGS. 1 and 2. The third electronic component 1c is disposed in an area including the third position P3 shown in FIGS. 1 and 2. The arrangement of the first to third detection circuits 110a to 110c is the same as that of the first to third detection circuits 10a to 10c in the first example embodiment.

FIG. 15 also shows a reference coordinate system defined based on the reference axis C shown in FIGS. 1 and 2. The definitions of the U, V, W, and Z directions are the same as in the first example embodiment.

The first structural body 120a has a structure for a first magnetic detection element to detect the target magnetic field MF at the first position P1 (first partial magnetic field). Like the first example embodiment, the first magnetic detection element has sensitivity in a direction intersecting the reference axis C.

The first detection circuit 110a includes the first magnetic detection element. In the example embodiment, the first detection circuit 110a includes two MR elements 111a and 112a as the first magnetic detection element. The first detection circuit 110a further includes a power supply port V11, a ground port G11, and an output port E11. The MR element 111a is provided between the power supply port V11 and the output port E11 in the circuit configuration. The MR element 112a is provided between the ground port G11 and the output port E11 in the circuit configuration. A voltage or current of predetermined magnitude is applied to the power supply port V11. The ground port G11 is grounded.

The second structural body 120b has a structure for a second magnetic detection element to detect the target magnetic field MF at the second position P2 (second partial magnetic field). Like the first example embodiment, the second magnetic detection element has sensitivity in a direction intersecting the reference axis C.

The second detection circuit 110b includes the second magnetic detection element. In the example embodiment, the second detection circuit 110b includes two MR elements 111b and 112b as the second magnetic detection element. The second detection circuit 110b further includes a power supply port V12, a ground port G12, and an output port E12. The MR element 111b is provided between the power supply port V12 and the output port E12 in the circuit configuration. The MR element 112b is provided between the ground port G12 and the output port E12 in the circuit configuration. A voltage or current of predetermined magnitude is applied to the power supply port V12. The ground port G12 is grounded.

The third structural body 120c has a structure for a third magnetic detection element to detect the target magnetic field MF at the third position P3 (third partial magnetic field). Like the first example embodiment, the third magnetic detection element has sensitivity in a direction intersecting the reference axis C.

The third detection circuit 110c includes the third magnetic detection element. In the example embodiment, the third detection circuit 110c includes two MR elements 111c and 112c as the third magnetic detection element. The third detection circuit 110c further includes a power supply port V13, a ground port G13, and an output port E13. The MR element 111c is provided between the power supply port V13 and the output port E13 in the circuit configuration. The MR element 112c is provided between the ground port G13 and the output port E13 in the circuit configuration. A voltage or current of predetermined magnitude is applied to the power supply port V13. The ground port G13 is grounded.

Any pair of a detection circuit and a structural body among the pair of the first detection circuit 110a and the first structural body 120a, the pair of the second detection circuit 110b and the second structural body 120b, and the pair of the third detection circuit 110c and the third structural body 120c will be denoted by the reference numerals 110 and 120, respectively. Of the MR elements included in the detection circuit 110, one corresponding to the MR element 111a, 111b, or 111c will be denoted by the reference numeral 111, and one corresponding to the MR element 112a, 112b, or 112c by the reference numeral 112.

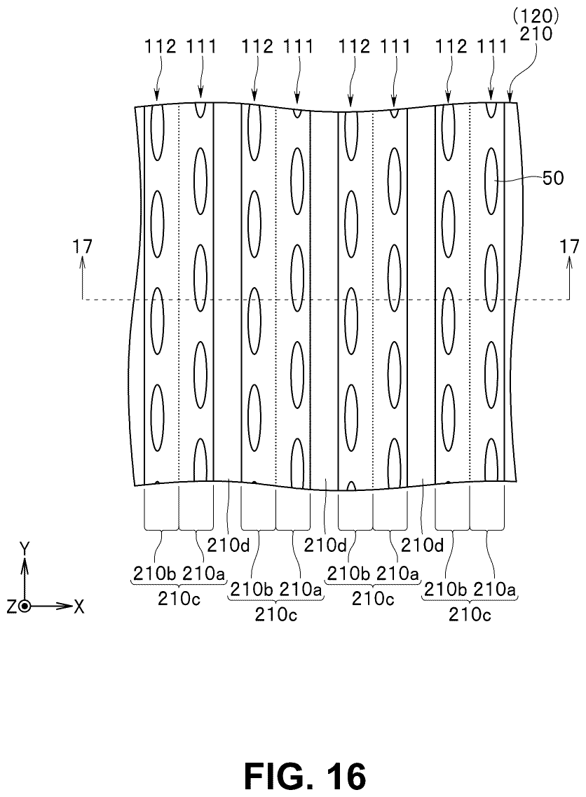

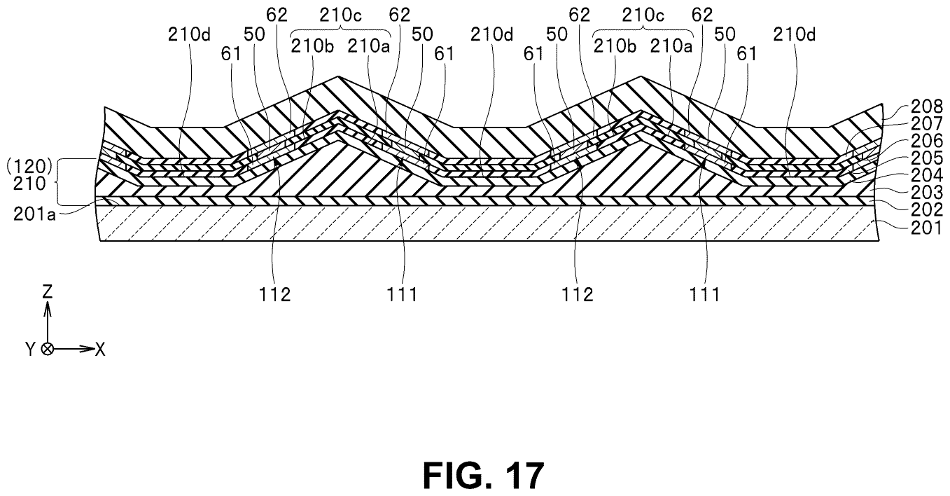

A configuration of the detection circuit 110 and the structural body 120 will be described in detail below with reference to FIGS. 16 and 17. FIG. 16 is a plan view showing a part of both the detection circuit 110 and the structural body 120. FIG. 17 is a sectional view showing a part of both the detection circuit 110 and the structural body 120. FIG. 17 shows a part of the section at the position indicated by the line 17-17 in FIG. 16.

An X direction, a Y direction, and a Z direction will be defined as shown in FIGS. 16 and 17. The X, Y, and Z directions are orthogonal to each other. The orthogonal coordinate system defined by the X, Y, and Z directions shown in FIGS. 16 and 17 is a coordinate system defined with reference to the pair of the detection circuit 110 and the structural body 120. The Z direction of this orthogonal coordinate system agrees with the Z direction of the reference coordinate system shown in FIG. 15.

The magnetic sensor 1 according to the example embodiment includes a substrate 201 having a top surface 201a, and insulating layers 202, 203, 204, 205, 206, 207, and 208. The top surface 201a of the substrate 201 is assumed to be parallel to the XY plane. The Z direction is also a direction perpendicular to the top surface 201a of the substrate 201. Each of the MR elements 111 and 112 includes a plurality of layered films 50 having the same configuration as in the first example embodiment. Wiring portions 60 in the example embodiment include a plurality of lower electrodes 61 and a plurality of upper electrodes 62.

The insulating layers 202, 203, and 204 are stacked on the substrate 201 in this order. The plurality of lower electrodes 61 are disposed on the insulating layer 204. The insulating layer 205 is disposed around the plurality of lower electrodes 61 on the insulating layer 204. The plurality of layered films 50 are disposed on the plurality of lower electrodes 61. The insulating layer 206 is disposed around the plurality of layered films 50 on the plurality of lower electrodes 61 and the insulating layer 205. The plurality of upper electrodes 62 are disposed on the plurality of layered films 50 and the insulating layer 206. The insulating layer 207 is disposed around the plurality of upper electrodes 62 on the insulating layer 206. The insulating layer 208 is disposed on the plurality of upper electrodes 62 and the insulating layer 207.

Each lower electrode 61 has a long slender shape in a direction parallel to the Y direction. There is a gap formed between two lower electrodes 61 adjacent in the longitudinal direction of the lower electrodes 61. Layered films 50 are disposed on the top surface of each lower electrode 61, near both ends in the longitudinal direction. Each upper electrode 62 has a long slender shape in the direction parallel to the Y direction, and electrically connects two adjacent layered films 50 disposed on two lower electrodes 61 adjacent in the longitudinal direction of the lower electrodes 61.

Although not shown in the diagram, a layered film 50 located at an end of a row of a plurality of layered films 50 arranged in the direction parallel to the Y direction is connected to another layered film 50 located at an end of another row of a plurality of layered films 50 adjacent in a direction parallel to the X direction. The two layered films 50 are connected to each other by a not-shown electrode. The not-shown electrode may be an electrode connecting the lower surfaces or the upper surfaces of the two layered films 50 to each other.

The structural body 120 includes a support member 210. The support member 210 is composed of the insulating layers 202, 203, and 204. FIG. 16 shows the support member 210 and a plurality of layered films 50 of each of the MR elements 111 and 112 among the components of the magnetic sensor 1.

The support member 210 has a plurality of protruding surfaces 210c each protruding in a direction away from the top surface 201a of the substrate 201 (Z direction). Each of the plurality of protruding surfaces 210c extends in the direction parallel to the Y direction. In the example shown in FIG. 17, each of the plurality of protruding surfaces 210c has a triangular roof-like overall shape formed by moving the triangular shape of the protruding surface 210c shown in FIG. 17 in a direction parallel to the U direction. The plurality of protruding surfaces 210c are arranged in the direction parallel to the X direction at a predetermined distance from each other.

The protruding surfaces 210c in the section shown in FIG. 17 may have a curved shape (arch shape). In such a case, each of the plurality of protruding surfaces 210c has a semicylindrical curved overall shape formed by moving the curved shape (arch shape) of the protruding surface 210c in the direction parallel to the Y direction.

Each of the plurality of protruding surfaces 210c has an upper end farthest from the top surface 201a of the substrate 201. In the example embodiment, the upper end of each of the plurality of protruding surfaces 210c is assumed to extend in the direction parallel to the Y direction. Now, focus on one of the plurality of protruding surfaces 210c. The protruding surface 210c includes a first inclined surface 210a and a second inclined surface 210b. The first inclined surface 210a refers to the area of the protruding surface 210c on the X-direction side of the top end of the protruding surface 210c. The second inclined surface 210b refers to the area of the protruding surface 210c on the −X-direction side of the top end of the protruding surface 210c. FIG. 16 shows the border between the first inclined surface 210a and the second inclined surface 210b in a dotted line.

The upper end of the protruding surface 210c may be the border between the first inclined surface 210a and the second inclined surface 210b. In such a case, the dotted lines shown in FIG. 16 represent the upper ends of the protruding surfaces 210c.

The top surface 201a of the substrate 201 is parallel to the XY plane and parallel to the reference plane described in the first example embodiment. Each of the first and second inclined surfaces 210a and 210b is inclined relative to the top surface 201a of the substrate 201, i.e., the reference plane. In a section perpendicular to the top surface 201a of the substrate 201, the distance between the first inclined surface 210a and the second inclined surface 210b decreases as the distance from the top surface 201a of the substrate 201 increases.

In the example shown in FIG. 17, each of the first and second inclined surfaces 210a and 210b is a flat surface. If the protruding surfaces 210c in the section shown in FIG. 17 have a curved shape (arch shape), each of the first and second inclined surfaces 210a and 210b is a curved surface.

In the example embodiment, there are a plurality of protruding surfaces 210c, and thus a plurality of first inclined surfaces 210a and a plurality of second inclined surfaces 210b. The support member 210 has the plurality of first inclined surfaces 210a and the plurality of second inclined surfaces 210b.

The support member 210 further has a flat surface 210d around the plurality of protruding surfaces 210c. The flat surface 210d is a surface parallel to the top surface 201a of the substrate 201. Each of the plurality of protruding surfaces 210c protrudes from the flat surface 210d in the Z direction. In the example embodiment, the plurality of protruding surfaces 210c are arranged at a predetermined distance from each other. Thus, there exists the flat surface 210d between two protruding surfaces 210c adjacent in the direction parallel to the X direction.

In the example embodiment, the plurality of protruding surfaces 210c and the flat surface 210d are substantially formed by the insulating layer 203. In other words, the insulating layer 203 includes a plurality of protrusions each protruding in the Z direction and a flat portion around the plurality of protrusions. Each of the plurality of protrusions extends in the direction parallel to the Y direction and has a top surface with a shape corresponding to the protruding surface 210c. The plurality of protrusions are arranged in the direction parallel to the X direction at a predetermined distance from each other. The flat portion has a substantially constant thickness (dimension in the Z direction). The insulating layer 204 has a substantially constant thickness (dimension in the Z direction) and is formed along the top surface of the insulating layer 203. The top surface of the insulating layer 204 thus forms the plurality of protruding surfaces 210c and the flat surface 210d.

The insulating layer 202 has a substantially constant thickness (dimension in the Z direction) and is formed along the bottom surface of the insulating layer 203.

A plurality of lower electrodes 61 for electrically connecting the plurality of layered films 50 of the MR element 111 are disposed on the plurality of first inclined surfaces 210a. A plurality of lower electrodes 61 for electrically connecting the plurality of layered films 50 of the MR element 112 are disposed on the plurality of second inclined surfaces 210b. As described above, each of the first and second inclined surfaces 210a and 210b is inclined relative to the top surface 201a of the substrate 201, i.e., the reference plane. The top surface of each of the plurality of lower electrodes 61 is thus also inclined relative to the reference plane. The MR elements 111 and 112 can therefore be said to be disposed on inclined surfaces inclined relative to the reference plane. The support member 210 is a member for supporting each of the MR elements 111 and 112 as inclined relative to the reference plane.

The magnetization of the magnetization pinned layer 52 in each of the plurality of layered films 50 of the MR element 111 includes a component in a first magnetization direction rotated from the −X direction toward the Z direction by an angle α. The magnetization of the magnetization pinned layer 52 in each of the plurality of layered films 50 of the MR element 112 includes a component in a second magnetization direction rotated from the −X direction toward the −Z direction by an angle β. The angles α and β are both within the range of more than 0° and less than 90°.

Each of the plurality of first inclined surfaces 210a may be a flat surface parallel to the first magnetization direction and the Y direction. Each of the plurality of second inclined surfaces 210b may be a flat surface parallel to the second magnetization direction and the Y direction.

In the present example embodiment, when there is no target magnetic field MF, the direction of the magnetization of the free layer 54 of the layered film 50 is parallel to the Y direction. If the direction of the target magnetic field MF applied to the detection circuit 110 is the Z direction, the direction of the magnetization of the free layer 54 in each of the plurality of the layered films 50 of the MR element 111 tilts from the direction parallel to the Y direction toward the first magnetization direction, and the direction of the magnetization of the free layer 54 in each of the plurality of layered films 50 of the MR element 112 tilts from the direction parallel to the Y direction toward a direction opposed to the second magnetization direction. As a result, the resistance of each of the plurality of layered films 50 of the MR element 111 decreases and the resistance of each of the plurality of layered films 50 of the MR element 112 increases compared to when there is no magnetic field component. Consequently, the resistance of the MR element 111 decreases and the resistance of the MR element 112 increases.

If the direction of the target magnetic field MF applied to the detection circuit 110 is the −Z direction, the changes in the resistances of the respective MR elements 111 and 112 are opposite to those in the foregoing case where the direction of the target magnetic field MF is the Z direction.

The amount of change in the resistance of each of the MR elements 111 and 112 depends on the strength of the component of the target magnetic field MF applied to the detection circuit 110 in the direction parallel to the Z direction. As the strength of the component increases, the resistance of each of the MR elements 111 and 112 changes so that the amount of increase or the amount of decrease increases. As the strength of the component decreases, the resistance of each of the MR elements 111 and 112 changes so that the amount of increase or the amount of decrease decreases.

In such a manner, when the direction and strength of the target magnetic field MF applied to the detection circuit 110 change, the resistance of each of the MR elements 111 and 112 changes so that the resistance of the MR element 111 increases and the resistance of the MR element 112 decreases, or so that the resistance of the MR element 111 decreases and the resistance of the MR element 112 increases. As a result, the potential at the connection point of the MR elements 111 and 112 changes. This potential changes with the angle that the direction of the magnetization of the free layer 54 forms with the direction of the magnetization of the magnetization pinned layer 52.

The first detection circuit 110a generates a signal corresponding to the potential at the output port E11 connected to the connection point of the MR elements 111a and 112a as the first detection signal S1. The second detection circuit 110b generates a signal corresponding to the potential at the output port E12 connected to the connection point of the MR elements 111b and 112b as the second detection signal S2. The third detection circuit 110c generates a signal corresponding to the potential at the output port E13 connected to the connection point of the MR elements 111c and 112c as the third detection signal S3.

Next, a relationship between the reference coordinate system shown in FIG. 15 and the orthogonal coordinate system shown in FIGS. 16 and 17 will be described. In the example embodiment, for any of the first to third electronic components 1a to 1c, the Y direction of the orthogonal coordinate system agrees with the U direction of the reference coordinate system, and the X direction of the orthogonal coordinate system agrees with a direction 90° rotated from the U direction of the reference coordinate system toward the W direction of the reference coordinate system.

In FIG. 15, the MR elements 111a, 111b, 111c, 112a, 112b, and 112c are schematically shown by a figure representing a layered film 50 each. In the example embodiment, each of the first detection circuit 110a of the first electronic component 1a, the second detection circuit 110b of the second electronic component 1b, and the third detection circuit 110c of the third electronic component 1c includes a plurality of layered films 50 (see FIGS. 16 and 17), each of which has a shape long in the direction parallel to the U direction.

In FIG. 15, the first to third structural bodies 120a to 120c are schematically shown by a figure representing a protruding surface 210c each. In the present example embodiment, each of the first detection circuit 110a of the first electronic component 1a, the second detection circuit 110b of the second electronic component 1b, and the third detection circuit 110c of the third electronic component 1c includes a plurality of protruding surfaces 210c (see FIGS. 16 and 17), each of which has a shape long in the direction parallel to the U direction.

Next, a method for manufacturing the magnetic sensor 1 according to the example embodiment will be briefly described. The method for manufacturing the magnetic sensor 1 according to the example embodiment is basically the same as that of the first example embodiment. In the present example embodiment, in the step of forming the plurality of layered films 50, a plurality of initial layered films to later become the plurality of layered films 50 of the MR element 111 and a plurality of initial layered films to later become the plurality of layered films 50 of the MR element 112 may be both irradiated with the laser light while an external magnetic field in the −X direction is applied thereto.

A method for generating the angle detection value θs in the example embodiment may be the same as that of the first example embodiment or that of the second example embodiment. A magnetic sensor system 100 according to the present example embodiment may include the magnetic field generator 5 in the first example embodiment or the magnetic field generator 6 in the sixth example embodiment. The configuration, operation, and effects of the present example embodiment are otherwise the same as those of the first, second or sixth example embodiment.

### Eighth Example Embodiment

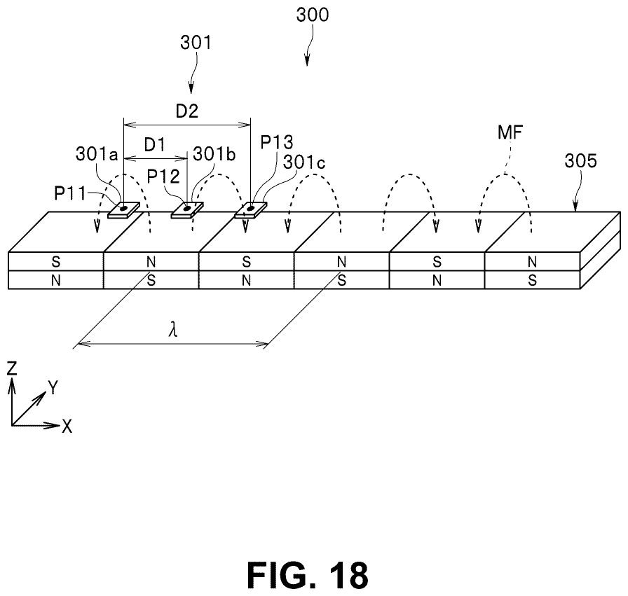

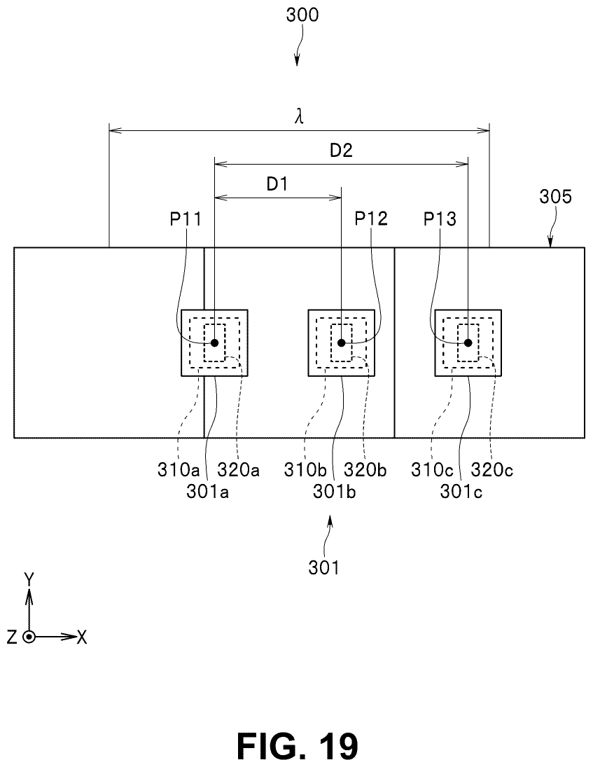

Next, a magnetic sensor 301 and a magnetic sensor system 300 according to an eighth example embodiment of the technology will be described with reference to FIGS. 18 and 19. FIG. 18 is a perspective view showing the magnetic sensor system 300 according to the example embodiment. FIG. 19 is a plan view showing the magnetic sensor system 300 according to the example embodiment. The magnetic sensor system 300 according to the example embodiment includes the magnetic sensor 301 according to the example embodiment and a magnetic field generator 305 that generates a target magnetic field MF.

The magnetic field generator 305 is a linear scale with a plurality of pairs of N and S poles magnetized in a linear direction. The magnetic sensor 301 or the magnetic field generator 305 can move along the longitudinal direction of the magnetic field generator 305.

An X direction, a Y direction, and a Z direction will be defined as shown in FIG. 18. In the present example embodiment, a direction parallel to the longitudinal direction of the magnetic field generator 305 is defined as the X direction. Two directions perpendicular to the X direction and orthogonal to each other are defined as the Y direction and the Z direction. The opposite direction to the X direction is referred to as a −X direction. The opposite direction to the Y direction is referred to as a −Y direction. The opposite direction to the Z direction is referred to as a −Z direction.

FIG. 18 shows the target magnetic field MF with broken-lined arrows denoted by the symbol MF. The target magnetic field MF includes a component in a direction orthogonal to the longitudinal direction of the magnetic field generator 305 (moving direction of the magnetic sensor 301 or the magnetic field generator 305), i.e., in a direction parallel to the Z direction. The magnetic sensor 301 and the magnetic field generator 305 are configured so that the strength of a component of the target magnetic field MF in the direction parallel to the Z direction at a specific position away from the magnetic field generator 305 changes when at least one of the magnetic sensor 301 or the magnetic field generator 305 operates. The strength of the foregoing component at a specific position has a correspondence with the position of the magnetic field generator 305 relative to the magnetic sensor 301, and changes with a change in the relative position.

The position of the magnetic field generator 305 relative to the magnetic sensor 301 will hereinafter be referred to as a relative position. The magnetic sensor 301 is configured to detect the target magnetic field MF and generate at least one detection signal having a correspondence with the relative position. In particular, in the example embodiment, the magnetic sensor 301 is configured to detect the target magnetic field MF at each of a plurality of specific positions away from the magnetic field generator 305 in the Z direction. In the following description, the target magnetic field MF at each of the plurality of specific positions will be described to include only a component of the target magnetic field MF in the Z direction.

As shown in FIG. 18, a distance between two adjacent N poles in the longitudinal direction of the magnetic field generator 305, or a center-to-center distance between two adjacent N poles with an S pole therebetween, will be referred to as a magnetic pole pitch. The magnitude of the magnetic pole pitch will be denoted by the symbol 2. The center-to-center distance between two adjacent S poles with an N pole therebetween is the same as the magnetic pole pitch 2.

The strength of the target magnetic field MF at a specific position changes periodically with a change in the relative position. In particular, in the present example embodiment, the strength of the target magnetic field MF at a specific position changes by one period as the relative position changes by the magnetic pole pitch 2.

The magnetic sensor 301 includes a first electronic component 301a including a first detection circuit 310a and a first structural body 320a, a second electronic component 301b including a second detection circuit 310b and a second structural body 320b, and a third electronic component 301c including a third detection circuit 310c and a third structural body 320c. The first to third electronic components 301a to 301c are located forward of the magnetic field generator 305 in the Z direction. Each of the first to third electronic components 301a to 301c may have a chip form or a package form sealed with a sealing resin.

The first to third detection circuits 310a to 310c and the first to third structural bodies 320a to 320c may have the same configuration as that of the detection circuit 10 and the structural body 20 in the first example embodiment, or that of the detection circuit 110 and the structural body 120 in the seventh example embodiment.

The first detection circuit 310a is configured to detect a first partial magnetic field that is the target magnetic field MF at a first position P11 away from the magnetic field generator 305 in the Z direction. The first structural body 320a has a structure for a first magnetic detection element to detect the target magnetic field MF at the first position P11 (first partial magnetic field). The first magnetic detection element has sensitivity in a direction intersecting the direction parallel to the Z direction. The first detection circuit 310a includes the first magnetic detection element.

The second detection circuit 310b is configured to detect a second partial magnetic field that is the target magnetic field MF at a second position P12 away from the magnetic field generator 305 in the Z direction. The second structural body 320b has a structure for a second magnetic detection element to detect the target magnetic field MF at the second position P12 (second partial magnetic field). The second magnetic detection element has sensitivity in a direction intersecting the direction parallel to the Z direction. The second detection circuit 310b includes the second magnetic detection element.

The third detection circuit 310c is configured to detect a third partial magnetic field that is the target magnetic field MF at a third position P13 away from the magnetic field generator 305 in the Z direction. The third structural body 320c has a structure for a third magnetic detection element to detect the target magnetic field MF at the third position P13 (third partial magnetic field). The third magnetic detection element has sensitivity in a direction intersecting the direction parallel to the Z direction. The third detection circuit 310c includes the third magnetic detection element.

If the first to third detection circuits 310a to 310c and the first to third structural bodies 320a to 320c have the same configuration as that of the detection circuit 10 and the structural body 20 in the first example embodiment, each of the plurality of layered films 50 (see FIGS. 5 to 8) in each of the first to third detection circuits 310a to 310c may have a shape long in the direction parallel to the Y direction. In such a case, each of the plurality of yokes 21 (seen FIGS. 5 to 7) in each of the first to third structural bodies 320a to 320c has a shape long in the direction parallel to the Y direction.

If the first to third detection circuits 310a to 310c and the first to third structural bodies 320a to 320c have the same configuration as that of the detection circuit 110 and the structural body 120 in the seventh example embodiment, each of the plurality of layered films 50 (see FIGS. 16 and 17) in each of the first to third detection circuits 310a to 310c may have a shape long in the direction parallel to the Y direction. In such a case, each of the plurality of protruding surfaces 210c (see FIGS. 16 and 17) in each of the first to third structural bodies 320a to 320c has a shape long in the direction parallel to the Y direction.

The description of the change in the strength of the target magnetic field MF at a specific position also applies to the first to third partial magnetic fields. The strength of each of the first to third partial magnetic fields changes periodically with a change in the relative position. The first detection circuit 310a is configured to generate a first detection signal that changes periodically depending on the periodic change in the first partial magnetic field. The second detection circuit 310b is configured to generate a second detection signal that changes periodically depending on the periodic change in the second partial magnetic field. The third detection circuit 310c is configured to generate a third detection signal that changes periodically depending on the periodic change in the third partial magnetic field.

The first to third detection signals include respective periodic components that change with the same period. In the present example embodiment, as the relative position changes by the magnetic pole pitch 2, the periodic components change by one period.

The first to third positions P11 to P13 will now be described in detail. Each of the first to third positions P11 to P13 may be a position on an imagery line that is located away from the magnetic field generator 305 in the Z direction and extends in the direction parallel to the X direction.

As shown in FIG. 18, the second position P12 is located away from the first position P11 by a distance D1 in the X direction. The third position P13 is located away from the first position P11 by a distance D2 in the X direction.

Suppose that m and n are both integers greater than or equal to 0. The distance D1 is (λ/3+m×λ). The distance D2 is (2λ/3+n×λ). In the example shown in FIG. 18, m and n are both 0.

The magnetic sensor system 300 further includes a not-shown processor that generates a detection value having a correspondence with the position of the magnetic sensor 301 or the magnetic field generator 305 based on the first to third detection signals. A method for generating the detection value in the example embodiment will now be described. The processor initially generates an initial detection value using the first to third detection signals. A method for generating the initial detection value is the same as the method for generating the angle detection value θs in the first or second example embodiment. The processor also counts the number of revolutions of the electric angle from a reference position, with one period of the initial detection value as an electrical angle of 360°. One revolution of the electrical angle is equivalent to the amount of movement of the relative position as much as the magnetic pole pitch λ. The processor generates the detection value having a correspondence with the relative position based on the initial detection value and the number of revolutions of the electrical angle.

The configuration, operation, and effects of the present example embodiment are otherwise the same as those of the first, second or seventh example embodiment.

### Ninth Example Embodiment

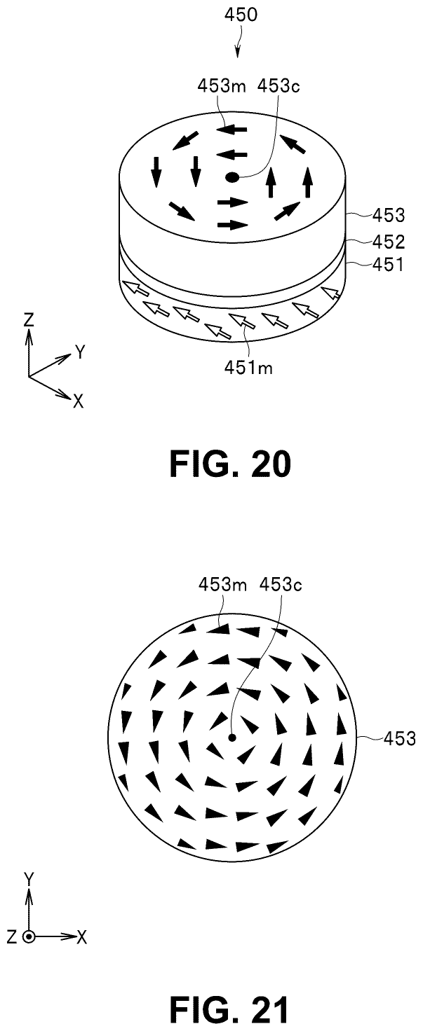

Next, a ninth example embodiment of the technology will be described with reference to FIGS. 20 and 21. The present example embodiment differs from the first to eighth example embodiments in the configuration of the layered films of the MR elements. FIG. 20 is a perspective view showing a layered film of an MR element in the example embodiment. FIG. 21 is a plan view showing a free layer of the layered film of the MR element in the example embodiment.

A layered film 450 in the example embodiment includes a magnetization pinned layer 451 having a magnetization 451m whose direction is fixed, a free layer 453, and a gap layer 452 located between the magnetization pinned layer 451 and the free layer 453. The material and shape of the free layer 453 are selected so that the free layer 453 has a magnetic vortex structure (also referred to as a vortex structure). The gap layer 452 is a tunnel barrier layer or a nonmagnetic conductive layer.

The free layer 453 has a cylindrical or substantially cylindrical shape. The free layer 453 has a magnetization 453m that is vortical about a center 453c of the magnetic vortex structure. When there is no magnetic field applied to the layered film 450, the center 453c of the magnetic vortex structure agrees or substantially agrees with the axis of the cylinder. The center 453c of the magnetic vortex structure moves depending on the target magnetic field MF. In the example shown in FIG. 20, the layered film 450 has a cylindrical overall shape.

An X direction, a Y direction, and a Z direction will be defined as shown in FIGS. 20 and 21. The X, Y, and Z directions are orthogonal to each other. In the example embodiment, the stacking direction of the magnetization pinned layer 451, the gap layer 452, and the free layer 453 is defined as the Z direction. The opposite direction to the X direction is referred to as a −X direction. The opposite direction to the Y direction is referred to as a −Y direction. The opposite direction to the Z direction is referred to as a −Z direction. The orthogonal coordinate system defined by the X, Y, and Z directions shown in FIGS. 20 and 21 is a coordinate system defined with reference to the layered film 450.

The center 453c of the magnetic vortex structure moves if a component of the target magnetic field MF in a direction orthogonal to the Z direction is applied to the free layer 453. The free layer 453 desirably does not saturate within the range of variations in the strength of the component.

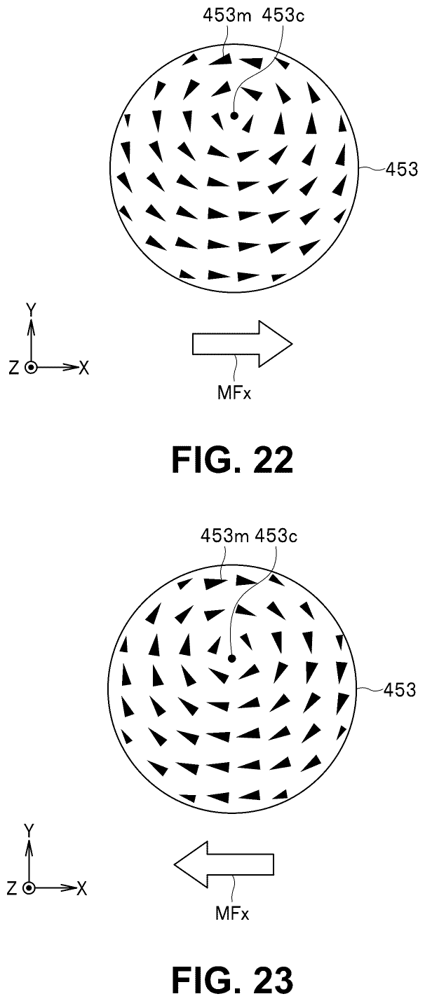

The resistance of the layered film 450 will now be described by using an example case where the direction of the magnetization 451m of the magnetization pinned layer 451 is the −X direction. FIGS. 22 and 23 show the free layer 453 when a magnetic field component MFx of the target magnetic field MF in a direction parallel to the X direction is applied to the free layer 453.

FIG. 22 shows the free layer 453 when the direction of the magnetic field component MFx is the X direction. In such a case, the center 453c of the magnetic vortex structure moves due to the magnetic field component MFx, and the direction of the magnetization of the entire free layer 453 becomes the X direction. Here, the resistance of the layered film 450 increases.

FIG. 23 shows the free layer 453 when the direction of the magnetic field component MFx is the −X direction. In such a case, the center 453c of the magnetic vortex structure moves due to the magnetic field component MFx, and the direction of the magnetization of the entire free layer 453 becomes the −X direction. Here, the resistance of the layered film 450 decreases.

The amount of change in the resistance of the layered film 450 depends on the strength of the magnetic field component MFx. As the strength of the magnetic field component MFx increases, the resistance of the layered film 450 changes so that the amount of increase or the amount of decrease increases. As the strength of the magnetic field component MFx decreases, the resistance of the layered film 450 changes so that the amount of increase or the amount of decrease decreases. In particular, in the example embodiment, the relationship between the strength of the magnetic field component MFx and the resistance of the layered film 450 is linear or substantially linear as long as the requirement that the free layer 453 not saturate is satisfied.

The configuration, operation, and effects of the present example embodiment are otherwise the same as those of any of the first to eighth example embodiments.

The technology is not limited to the foregoing example embodiments, and various modifications can be made. For example, the first to third structural bodies may be integrated. In other words, if the first to third structural bodies include a yoke each, the first to third structural bodies may be made of a soft magnetic body.

As described above, a magnetic sensor according to the technology is configured to detect a target magnetic field including a component in a direction parallel to a reference axis. The magnetic sensor according to the technology includes: a first structural body having a structure for a first magnetic detection element to detect a first partial magnetic field that is the target magnetic field at a first position away from the reference axis; a second structural body having a structure for a second magnetic detection element to detect a second partial magnetic field that is the target magnetic field at a second position away from the reference axis; a third structural body having a structure for a third magnetic detection element to detect a third partial magnetic field that is the target magnetic field at a third position away from the reference axis; a first detection circuit including the first magnetic detection element and configured to generate a first detection signal that changes periodically depending on a periodic change in the first partial magnetic field; a second detection circuit including the second magnetic detection element and configured to generate a second detection signal that changes periodically depending on a periodic change in the second partial magnetic field; and a third detection circuit including the third magnetic detection element and configured to generate a third detection signal that changes periodically depending on a periodic change in the third partial magnetic field.

The first detection signal, the second detection signal, and the third detection signal include respective periodic components that change with a same period. The second position is a position rotated from the first position by an angle equivalent to an electrical angle of (120+360×m)° circumferentially about the reference axis, and the third position is a position rotated from the first position by an angle equivalent to an electrical angle of (240+360×n)° circumferentially about the reference axis, where the period of the periodic components is an electrical angle of 360°, and m and n are both integers greater than or equal to 0.

In the magnetic sensor according to the technology, the first structural body may include a first yoke formed of a soft magnetic body and configured to generate a first magnetic field component in a direction parallel to a first direction intersecting the reference axis based on the first partial magnetic field. The second structural body may include a second yoke formed of a soft magnetic body and configured to generate a second magnetic field component in a direction parallel to a second direction intersecting the reference axis based on the second partial magnetic field. The third structural body may include a third yoke formed of a soft magnetic body and configured to generate a third magnetic field component in a direction parallel to a third direction intersecting the reference axis based on the third partial magnetic field. The first magnetic detection element may be located at a position where the first magnetic field component is applied. The second magnetic detection element may be located at a position where the second magnetic field component is applied. The third magnetic detection element may be located at a position where the third magnetic field component is applied.

In the magnetic sensor according to the technology, the first structural body may include a first support member having a first inclined surface inclined relative to a reference plane perpendicular to the reference axis. The second structural body may include a second support member having a second inclined surface inclined relative to the reference plane. The third structural body may include a third support member having a third inclined surface inclined relative to the reference plane. The first magnetic detection element may be disposed on the first inclined surface. The second magnetic detection element may be disposed on the second inclined surface. The third magnetic detection element may be disposed on the third inclined surface.

In the magnetic sensor according to the technology, the first magnetic detection element, the second magnetic detection element, and the third magnetic detection element may change their characteristics depending on a change in a strength of the component of the target magnetic field in the direction parallel to the reference axis. The first magnetic detection element may have sensitivity in a first direction intersecting the reference axis. The second magnetic detection element may have sensitivity in a second direction intersecting the reference axis. The third magnetic detection element may have sensitivity in a third direction intersecting the reference axis.

In the magnetic sensor according to the technology, each of the first, second, and third magnetic detection elements may include two magnetoresistive elements. Each of the two magnetoresistive elements may include a magnetization pinned layer having a magnetization whose direction is fixed and a free layer having a magnetization whose direction is variable depending on the target magnetic field. In such a case, the magnetization of the magnetization pinned layer of one of the two magnetoresistive elements and the magnetization of the magnetization pinned layer of the other of the two magnetoresistive elements may include components in the same direction. Alternatively, each of the two magnetoresistive elements may include a magnetization pinned layer having a magnetization whose direction is fixed and a free layer having a magnetic vortex structure and configured so that a center of the magnetic vortex structure moves depending on the target magnetic field.

The magnetic sensor according to the technology may further include a shield for shielding the first magnetic detection element, the second magnetic detection element, and the third magnetic detection element from an external magnetic field in a direction orthogonal to the reference axis.

A magnetic sensor device according to the technology includes the magnetic sensor according to the technology and a processor configured to generate an angle detection value having a correspondence with a target angle based on the first detection signal, the second detection signal, and the third detection signal.

In the magnetic sensor device according to the technology, the processor may be configured to generate the angle detection value using a first signal equivalent to a difference between the first and second detection signals, a second signal equivalent to a difference between the second and third detection signals, and a third signal equivalent to a difference between the third and first detection signals. Alternatively, the processor may be configured to generate a first calculated signal by a calculation including determination of a first signal and a second signal, the first signal being equivalent to a difference between the first and second detection signals, the second signal being equivalent to a difference between the second and third detection signals, generate a second calculated signal by a calculation including determination of a sum of the first signal and the second signal, and generate the angle detection value using the first calculated signal and the second calculated signal

In the magnetic sensor device according to the technology, the processor may generate the angle detection value by performing a calculation using the first, second, and third detection signals so that an error in the angle detection value due to a noise magnetic field other than the target magnetic field for the magnetic sensor to detect decreases compared to a case where the angle detection value is generated without generating at least one signal equivalent to a difference between two of the first, second, and third detection signals.

A magnetic sensor system according to a first aspect of the technology includes the magnetic sensor according to the technology and a magnetic field generator configured to generate the target magnetic field. The magnetic sensor and the magnetic field generator are configured so that a strength of the component of the target magnetic field in the direction parallel to the reference axis at each of the first, second, and third positions changes when at least either the magnetic sensor or the magnetic field generator rotates about the reference axis.

In the magnetic sensor system according to the first aspect of the technology, the magnetic sensor may further include a support located at a predetermined distance from the magnetic field generator in the direction parallel to the reference axis, the support having a top surface opposed to the magnetic field generator. The first structural body, the second structural body, the third structural body, the first detection circuit, the second detection circuit, and the third detection circuit may be disposed on the top surface of the support.

In the magnetic sensor system according to the first aspect of the technology, the magnetic field generator may include k pairs of N and S poles, where k is an integer greater than or equal to 1. The N poles may have a magnetization in a direction parallel to the reference axis. The S poles may have a magnetization in a direction opposite to that of the magnetization of the N poles. The second position may be a position rotated from the first position by (120/k+360×m/k°) circumferentially about the reference axis, and the third position may be a position rotated from the first position by (240/k+360×n/k)° circumferentially about the reference axis.

A magnetic sensor system according to a second aspect of the technology includes a magnetic field generator configured to generate a target magnetic field, and a magnetic sensor configured to detect the target magnetic field. The magnetic sensor includes a first structural body having a structure for a first magnetic detection element to detect a first partial magnetic field that is the target magnetic field at a first position away from the magnetic field generator in a first direction, a second structural body having a structure for a second magnetic detection element to detect a second partial magnetic field that is the target magnetic field at a second position away from the magnetic field generator in the first direction, a third structural body having a structure for a third magnetic detection element to detect a third partial magnetic field that is the target magnetic field at a third position away from the magnetic field generator in the first direction, a first detection circuit including the first magnetic detection element, a second detection circuit including the second magnetic detection element, and a third detection circuit including the third magnetic detection element.

The magnetic field generator is a magnetic scale including a plurality of pairs of N and S poles arranged alternately. The magnetic sensor and the magnetic field generator are configured so that strengths of components of the target magnetic field in the first direction at the first, second, and third positions change when at least either the magnetic sensor or the magnetic field generator operates in a direction parallel to a second direction intersecting the first direction. The second position is a position away from the first position by (λ/3+m×λ) in the second direction, and the third position is a position away from the first position by (2λ/3+n×2) in the second direction, where A is a center-to-center distance of two adjacent N poles with an S pole therebetween in the magnetic field generator, and m and n are both integers greater than or equal to 0.

Obviously, many modifications and variations of the technology are possible in the light of the above teachings. Thus, it is to be understood that, within the scope of the appended claims and equivalents thereof, the technology may be practiced in other example embodiments than the foregoing example embodiments.

What is claimed is:

1. A magnetic sensor configured to detect a target magnetic field including a component in a direction parallel to a reference axis, the magnetic sensor comprising:
a first structural body having a structure for a first magnetic detection element to detect a first partial magnetic field that is the target magnetic field at a first position away from the reference axis;
a second structural body having a structure for a second magnetic detection element to detect a second partial magnetic field that is the target magnetic field at a second position away from the reference axis;
a third structural body having a structure for a third magnetic detection element to detect a third partial magnetic field that is the target magnetic field at a third position away from the reference axis;
a first detection circuit including the first magnetic detection element and configured to generate a first detection signal that changes periodically depending on a periodic change in the first partial magnetic field;
a second detection circuit including the second magnetic detection element and configured to generate a second detection signal that changes periodically depending on a periodic change in the second partial magnetic field; and
a third detection circuit including the third magnetic detection element and configured to generate a third detection signal that changes periodically depending on a periodic change in the third partial magnetic field, wherein
the first detection signal, the second detection signal, and the third detection signal include respective periodic components that change with a same period, the second position is a position rotated from the first position by an angle equivalent to an electrical angle of (120+360×m)° circumferentially about the reference axis, and the third position is a position rotated from the first position by an angle equivalent to an electrical angle of (240+360×n)° circumferentially about the reference axis, where a period of the periodic components is an electrical angle of 360°, and m and n are both integers greater than or equal to 0.

2. The magnetic sensor according to claim 1, wherein:
the first structural body includes a first yoke formed of a soft magnetic body and configured to generate a first magnetic field component in a direction parallel to a first direction intersecting the reference axis based on the first partial magnetic field;
the second structural body includes a second yoke formed of a soft magnetic body and configured to generate a second magnetic field component in a direction parallel to a second direction intersecting the reference axis based on the second partial magnetic field;
the third structural body includes a third yoke formed of a soft magnetic body and configured to generate a third magnetic field component in a direction parallel to a third direction intersecting the reference axis based on the third partial magnetic field;
the first magnetic detection element is located at a position where the first magnetic field component is applied;
the second magnetic detection element is located at a position where the second magnetic field component is applied; and
the third magnetic detection element is located at a position where the third magnetic field component is applied.

3. The magnetic sensor according to claim 1, wherein:
the first structural body includes a first support member having a first inclined surface inclined relative to a reference plane perpendicular to the reference axis;
the second structural body includes a second support member having a second inclined surface inclined relative to the reference plane;
the third structural body includes a third support member having a third inclined surface inclined relative to the reference plane;
the first magnetic detection element is disposed on the first inclined surface;
the second magnetic detection element is disposed on the second inclined surface; and
the third magnetic detection element is disposed on the third inclined surface.

4. The magnetic sensor according to claim 1, wherein the first magnetic detection element, the second magnetic detection element, and the third magnetic detection element change their characteristics depending on a change in a strength of the component of the target magnetic field in the direction parallel to the reference axis.

5. The magnetic sensor according to claim 4, wherein:
the first magnetic detection element has sensitivity in a first direction intersecting the reference axis;
the second magnetic detection element has sensitivity in a second direction intersecting the reference axis; and
the third magnetic detection element has sensitivity in a third direction intersecting the reference axis.

6. The magnetic sensor according to claim 1, wherein each of the first, second, and third magnetic detection elements includes two magnetoresistive elements.

7. The magnetic sensor according to claim 6, wherein:
each of the two magnetoresistive elements includes a magnetization pinned layer having a magnetization whose direction is fixed and a free layer having a magnetization whose direction is variable depending on the target magnetic field; and
the magnetization of the magnetization pinned layer of one of the two magnetoresistive elements and the magnetization of the magnetization pinned layer of another of the two magnetoresistive elements include components in a same direction.

8. The magnetic sensor according to claim 6, wherein each of the two magnetoresistive elements includes a magnetization pinned layer having a magnetization whose direction is fixed and a free layer having a magnetic vortex structure and configured so that a center of the magnetic vortex structure moves depending on the target magnetic field.

9. The magnetic sensor according to claim 1, further comprising a shield for shielding the first magnetic detection element, the second magnetic detection element, and the third magnetic detection element from an external magnetic field in a direction orthogonal to the reference axis.

10. A magnetic sensor device comprising:
the magnetic sensor according to claim 1; and
a processor configured to generate an angle detection value having a correspondence with a target angle based on the first detection signal, the second detection signal, and the third detection signal.

11. The magnetic sensor device according to claim 10, wherein the processor is configured to generate the angle detection value using a first signal equivalent to a difference between the first and second detection signals, a second signal equivalent to a difference between the second and third detection signals, and a third signal equivalent to a difference between the third and first detection signals.

12. The magnetic sensor device according to claim 10, wherein the processor is configured to:
generate a first calculated signal by a calculation including determination of a first signal and a second signal, the first signal being equivalent to a difference between the first and second detection signals, the second signal being equivalent to a difference between the second and third detection signals;
generate a second calculated signal by a calculation including determination of a sum of the first signal and the second signal; and
generate the angle detection value using the first calculated signal and the second calculated signal.

13. The magnetic sensor device according to claim 10, wherein the processor generates the angle detection value by performing a calculation using the first, second, and third detection signals so that an error in the angle detection value due to a noise magnetic field other than the target magnetic field for the magnetic sensor to detect decreases compared to a case where the angle detection value is generated without generating at least one signal equivalent to a difference between two of the first, second, and third detection signals.

14. A magnetic sensor system comprising:
the magnetic sensor according to claim 1; and
a magnetic field generator configured to generate the target magnetic field, wherein
the magnetic sensor and the magnetic field generator are configured so that a strength of the component of the target magnetic field in the direction parallel to the reference axis at each of the first, second, and third positions changes when at least one of the magnetic sensor or the magnetic field generator rotates about the reference axis.

15. The magnetic sensor system according to claim 14, wherein:
the magnetic sensor further includes a support located at a predetermined distance from the magnetic field generator in the direction parallel to the reference axis, the support having a top surface opposed to the magnetic field generator; and
the first structural body, the second structural body, the third structural body, the first detection circuit, the second detection circuit, and the third detection circuit are disposed on the top surface of the support.

16. The magnetic sensor system according to claim 14, wherein:
the magnetic field generator includes k pairs of N and S poles, where k is an integer greater than or equal to 1;
the N poles have a magnetization in a direction parallel to the reference axis;
the S poles have a magnetization in a direction opposite to that of the magnetization of the N poles; and
the second position is a position rotated from the first position by (120/k+360×m/k)° circumferentially about the reference axis, and the third position is a position rotated from the first position by (240/k+360×n/k)° circumferentially about the reference axis.

17. A magnetic sensor system comprising:
a magnetic field generator configured to generate a target magnetic field; and
a magnetic sensor configured to detect the target magnetic field, wherein
the magnetic sensor includes
a first structural body having a structure for a first magnetic detection element to detect a first partial magnetic field that is the target magnetic field at a first position away from the magnetic field generator in a first direction,
a second structural body having a structure for a second magnetic detection element to detect a second partial magnetic field that is the target magnetic field at a second position away from the magnetic field generator in the first direction,
a third structural body having a structure for a third magnetic detection element to detect a third partial magnetic field that is the target magnetic field at a third position away from the magnetic field generator in the first direction,
a first detection circuit including the first magnetic detection element,
a second detection circuit including the second magnetic detection element, and
a third detection circuit including the third magnetic detection element,
the magnetic field generator is a magnetic scale including a plurality of pairs of N and S poles arranged alternately,
the magnetic sensor and the magnetic field generator are configured so that strengths of components of the target magnetic field in the first direction at the first, second, and third positions change when at least one of the magnetic sensor or the magnetic field generator operates in a direction parallel to a second direction intersecting the first direction, and
the second position is a position away from the first position by (λ/3+m×λ) in the second direction, and the third position is a position away from the first position by (2λ/3+n×λ) in the second direction, where λ is a center-to-center distance of two adjacent N poles with an S pole therebetween in the magnetic field generator, and m and n are both integers greater than or equal to 0.
